(19) United States
(12) Patent Application Publication
(10) Pub. No.: US 2024/0397792 A1
(43) Pub. Date: Nov. 28, 2024

(54) DISPLAY DEVICE

(71) Applicant: Samsung Display Co., LTD., Yongin-si (KR)

(72) Inventors: HYOENG-KI KIM, Yongin-si (KR); HYUNHO KIM, Yongin-si (KR); HYEONBUM LEE, Yongin-si (KR); CHAUNGI CHOI, Yongin-si (KR); DONGUK KIM, Yongin-si (KR); Hoongi Lee, Yongin-si (KR)

(21) Appl. No.: 18/607,631

(22) Filed: Mar. 18, 2024

(30) Foreign Application Priority Data
May 23, 2023 (KR) 10-2023-0066474

(51) Int. Cl. H10K 59/80

(52) U.S. Cl. CPC H10K 59/873; H10K 59/8792

(57) ABSTRACT

A display device including a display module including a first region and a second region, a first support layer disposed under the display module, overlapping the first region and having a plurality of openings, and a second support layer disposed under the display module, spaced apart from the first support layer and overlapping the second region, a base layer including a display region adjacent a non-display region, a circuit layer on the base layer, a light emitting element layer disposed on the circuit layer and including a light emitting element, and an anti-reflective layer disposed on the light emitting element layer including an organic pattern and an overcoat layer covering the organic pattern. The circuit layer includes a dam structure disposed on the non-display region and a blocking member overlapping at least a portion of the dam structure on a plane and includes the same material as the organic pattern.

This application claims priority to Korean Patent Application No. 10-2023-0066474, filed on May 23, 2023, and all the benefits accruing therefrom under U.S.C. § 119, the content of which in its entirety is herein incorporated by reference.

### BACKGROUND

### 1. Field

Embodiments of the invention described herein relate to a display device, and more particularly, relate to a display device capable of an extension operation of a display surface.

### 2. Description of Related Art

A display device, such as a smart phone, a digital camera, a notebook computer, a car navigation unit, a smart television, or the like, provides an image to a user through a display screen. The display device may include a display panel that displays an image.

With the development of display device technology, various forms of display devices are being developed. For example, flexible display devices that can be folded or rolled are being developed. The flexible display devices that are deformable into various shapes may be easy to carry and thus may improve user convenience.

Among the flexible display devices, an extendable flexible display device may receive at least a portion of a display panel inside of a case or withdraw at least a portion of the display panel outside of the case as needed using folding characteristics of the display panel. Accordingly, a user may extend a display screen as needed. However, the extendable flexible display device has a problem in that the display panel is likely to be damaged by an extension operation.

### SUMMARY

Embodiments of the invention provide a display device for preventing a display panel from being damaged by an extension operation.

According to an embodiment, a display device includes a display module including a first region and a second region arranged to be directed in a first direction, a first support layer that is disposed under the display module and that overlaps the first region and has a plurality of openings defined therein, and a second support layer that is disposed under the display module and spaced apart from the first support layer in the first direction and that overlaps the second region. The display module includes a base layer including a display region and a non-display region located adjacent to the display region, a circuit layer disposed on the base layer, a light emitting element layer that is disposed on the circuit layer and that includes at least one light emitting element, and an anti-reflective layer that is disposed on the light emitting element layer and that includes at least one organic pattern and an overcoat layer that covers the at least one organic pattern. The circuit layer includes a dam structure that is disposed on the non-display region and that includes at least one dam and a blocking member that overlaps at least a portion of the dam structure on a plane and that includes the same material as the at least one organic pattern included in the anti-reflective layer. The overcoat layer has a thickness of about 10 micrometers to about 50 micrometers and overlaps at least a portion of the blocking member on the plane.

In an embodiment, the anti-reflective layer may include a black matrix that absorbs light, at least one color filter that transmits light having a specific wavelength, and the overcoat layer, wherein the overcoat layer covers the black matrix and the at least one color filter. The blocking member may include the same material as at least one of the black matrix and the at least one color filter.

In an embodiment, the blocking member may include the same material as the black matrix.

In an embodiment, the blocking member may include the same material as the at least one color filter.

In an embodiment, the blocking member may include a first blocking layer including the same material as the black matrix and a second blocking layer that is disposed on the first blocking layer, wherein the second blocking layer includes the same material as the at least one color filter.

In an embodiment, the dam structure may include a first dam disposed adjacent to the display region and a second dam spaced apart from the display region with the first dam disposed therebetween, and wherein a separation space may be defined between the first dam and the second dam.

In an embodiment, at least a portion of the blocking member may be disposed between the first dam and the second dam.

In an embodiment, the blocking member may overlap at least a part of the first dam and the second dam.

In an embodiment, the circuit layer may include a plurality of insulating layers, and the at least one dam may include at least one of the plurality of insulating layers.

In an embodiment, the overcoat layer may make contact with the blocking member.

In an embodiment, at least a portion of the first region of the display module may be folded about an axis that extends in a second direction crossing the first direction.

In an embodiment, the display module may further include a third region spaced apart from the first region with the second region disposed therebetween, wherein at least a portion of the third region may be folded about an axis that extends in the second direction.

In an embodiment, the display module may further include a fourth region spaced apart from the second region with the first region disposed therebetween, wherein an upper surface of the second region and an upper surface of the fourth region may face each other when at least a portion of the first region is in a folded state.

In an embodiment, the display device may further include a plurality of support bars disposed under the first support layer and spaced apart from each other in the first direction, wherein each of the plurality of support bars may extend in a second direction crossing the first direction.

In an embodiment, the plurality of support bars may not overlap the plurality of openings on the plane.

In an embodiment, the display device may further include a cover member that is disposed between the display module and the first support layer and that includes an elastic material.

According to an embodiment, a display device includes a display module including a first region and a second region arranged in a first direction, a first support layer that is disposed under the display module and that overlaps the first region and that has a plurality of openings defined therein, and a second support layer that is disposed under the display module and spaced apart from the first support layer to be directed in the first direction and that overlaps the second region. The display module includes a base layer including a display region and a non-display region disposed adjacent to the display region, a circuit layer disposed on the base layer, a light emitting element layer that is disposed on the circuit layer and that includes at least one light emitting element, and an anti-reflective layer disposed on the light emitting element layer. The anti-reflective layer includes a black matrix that absorbs light, at least one color filter that transmits light having a specific wavelength, and an overcoat layer that covers the black matrix and the at least one color filter. The circuit layer includes a dam structure that is disposed on the non-display region and that includes at least one dam and a blocking member that overlaps the dam structure on a plane and that includes the same material as the black matrix or the at least one color filter. The overcoat layer has a thickness of about 10 micrometers to about 50 micrometers.

In an embodiment, the dam structure may include a first dam disposed adjacent to the display region and a second dam spaced apart from the display region with the first dam disposed therebetween, wherein a portion of the blocking member may be disposed between the first dam and the second dam.

In an embodiment, the overcoat layer may make contact with the blocking member.

According to an embodiment, a display device operates in a first mode and a second mode, wherein when in the second mode, a display surface is further extended as compared with when the display device operates in the first mode. The display device includes a display module including a first region, at least a portion of which is folded in the first mode and a second region disposed adjacent to the first region. The display module includes a base layer including a display region and a non-display region disposed adjacent to the display region, a circuit layer disposed on the base layer, a light emitting element layer that is disposed on the circuit layer and that includes at least one light emitting element, and an anti-reflective layer that is disposed on the light emitting element layer and that includes at least one organic pattern and an overcoat layer that covers the at least one organic pattern. The circuit layer includes a dam structure that is disposed on the non-display region and that includes at least one dam and a blocking member that overlaps the dam structure on a plane and includes the same material as the at least one organic pattern included in the anti-reflective layer. The overcoat layer has a thickness of about 10 micrometers to about 50 micrometers and makes contact with at least a portion of the blocking member.

### BRIEF DESCRIPTION OF THE FIGURES

The above and other objects and features of the invention will become apparent by describing in detail embodiments thereof with reference to the accompanying drawings.

FIG. 1A is a perspective view of a display device, according to an embodiment.

FIG. 1B is a perspective view of a display device, according to an embodiment.

FIG. 2A is a side sectional view of the display device, according to an embodiment.

FIG. 2B is a side sectional view of the display device, according to an embodiment.

FIG. 3 is an exploded perspective view of the display device, according to an embodiment.

FIG. 4 is a sectional view of a display module, according to an embodiment.

FIG. 5 is a plan view of a display panel, according to an embodiment.

FIG. 6 is a sectional view of a portion of the display module, according to an embodiment.

FIG. 7 is a sectional view of a portion of the display module, according to an embodiment.

FIG. 8A is an enlarged sectional view of a portion of the display module, according to an embodiment.

FIG. 8B is an enlarged sectional view of a portion of the display module, according to an embodiment.

FIG. 8C is an enlarged sectional view of a portion of the display module, according to an embodiment.

FIG. 8D is an enlarged sectional view of a portion of the display module, according to an embodiment.

FIG. 9A is a perspective view of a display device, according to an embodiment.

FIG. 9B is a perspective view of a display device, according to an embodiment.

FIG. 10 is a side sectional view of the display device, according to an embodiment.

FIG. 11A is a perspective view of a display device, according to an embodiment.

FIG. 11B is a perspective view of a display device, according to an embodiment.

FIG. 11C is a perspective view of a display device, according to an embodiment.

FIG. 12A is an exploded perspective view of the display device, according to an embodiment.

FIG. 12B is a sectional view of the display device, according to an embodiment.

### DETAILED DESCRIPTION

In this disclosure, when it is mentioned that a component (or, an area, a layer, a part, etc.) is referred to as being “on”, “connected to” or “coupled to” another component, this means that the component may be directly on, connected to, or coupled to the other component or a third component may be present therebetween.

Identical reference numerals refer to identical components. Additionally, in the drawings, the thicknesses, proportions, and dimensions of components are exaggerated for effective description. As used herein, the term “and/or” includes all of one or more combinations defined by related components.

Terms such as first, second, and the like may be used to describe various components, but the components should not be limited by the terms. The terms may be used only for distinguishing one component from other components. For example, without departing the scope of the invention, a first component may be referred to as a second component, and similarly, the second component may also be referred to as the first component. The terms of a singular form may include plural forms unless otherwise specified.

In addition, terms such as “below”, “under”, “above”, and “over” are used to describe a relationship of components illustrated in the drawings. The terms are relative concepts and are described based on directions illustrated in the drawing.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

The expression “directly disposed” used herein may mean that there is no additional layer, film, area, or plate between one portion, such as a layer, a film, an area, or a plate, and another portion. For example, the expression “directly disposed” may mean that two layers or two members are disposed without an additional member such as an adhesive member therebetween.

Unless otherwise defined, all terms used herein, including technical or scientific terms, have the same meanings as those generally understood by those skilled in the art to which the invention pertains. Such terms as those defined in a generally used dictionary are to be interpreted as having meanings equal to the contextual meanings in the relevant field of art and are not to be interpreted as having ideal or excessively formal meanings unless clearly defined as having such in the present application.

Terms such as “part” and “unit” mean a software component or hardware component that performs a specific function. The hardware component may include, for example, a field-programmable gate array (FPGA) or an application-specific integrated circuit (ASIC). The software component may refer to an executable code and/or data used by the executable code in an addressable storage medium. Thus, the software components may be, for example, object-oriented software components, class components, and task components, and may include processes, functions, attributes, procedures, subroutines, program code segments, drivers, firmware, microcode, circuits, data, database, data structures, tables, arrays, or variables.

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

Hereinafter, embodiments of the invention will be described with reference to the accompanying drawings.

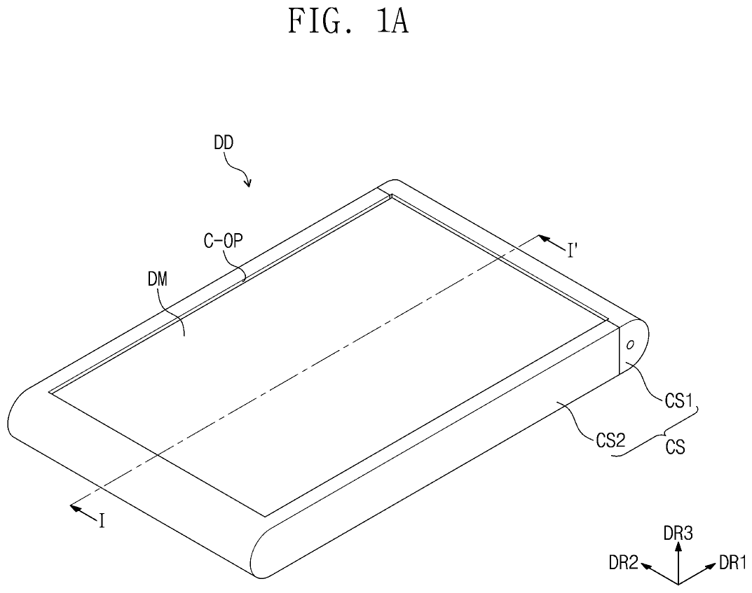

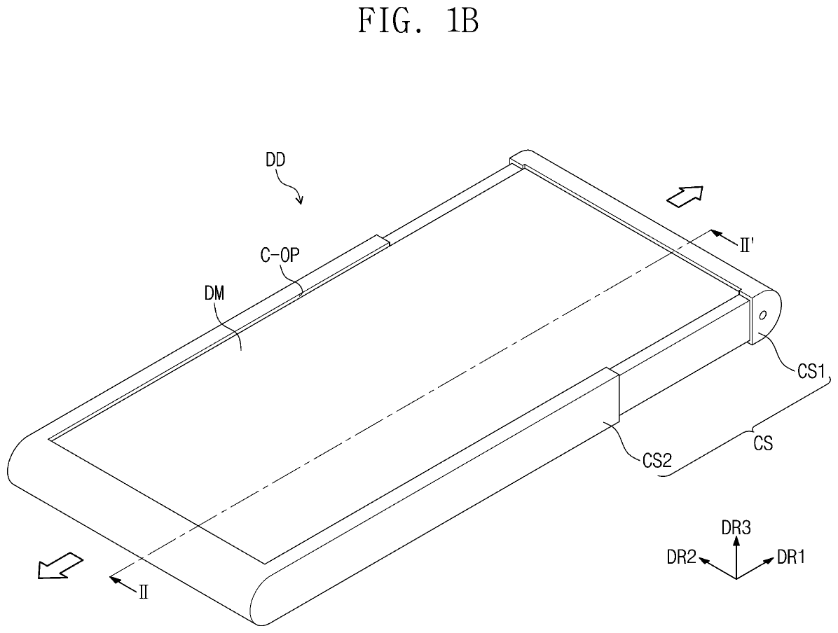

FIGS. 1A and 1B are perspective views of a display device according to an embodiment. FIG. 1A is a perspective view of the display device DD operating in a first mode, and FIG. 1B is a perspective view of the display device DD operating in a second mode.

In an embodiment, the display device DD may be activated depending on an electrical signal and may display an image. The display device DD may include various embodiments. For example, the display device DD may be a large device such as a television, a billboard, or the like, or may be a small and medium-sized device such as a monitor, a smart phone, a tablet computer, a car navigation unit, a game machine, or the like. In this embodiment, the display device DD is illustrated as a smart phone capable of a sliding operation.

In an embodiment and referring to FIGS. 1A and 1B, the display device DD may include a display module DM and a case CS in which the display module DM is accommodated. At least a portion of the display module DM may be exposed to the outside through a display opening C-OP defined in an upper portion of the case CS.

In an embodiment, the case CS may include a first case CS1 and a second case CS2. The first case CS1 and the second case CS2 may be coupled with each other and may accommodate the display module DM. The first case CS1 may be coupled to the second case CS2 to move in a direction parallel to a first direction DR1. The first case CS1 may be coupled to the second case CS2 and may move toward or away from the second case CS2.

In an embodiment, a display surface of the display module DM exposed by the display opening C-OP may be directed parallel to the first direction DR1 and a second direction DR2 crossing the first direction DR1. The display module DM may display an image in a third direction DR3 on the display surface that is directed parallel to the first direction DR1 and the second direction DR2.

In this specification, the third direction DR3 may be defined as a direction substantially vertically crossing a plane defined by the first direction DR1 and the second direction DR2. Front surfaces (or, upper surfaces) and rear surfaces (or, lower surfaces) of members constituting the display device DD may be disposed to be opposite to each other in the third direction DR3, and the normal directions of the front surfaces and the rear surfaces may be directed to be substantially parallel to the third direction DR3. The separation distance between a front surface and a rear surface that is defined in the third direction DR3 may correspond to the thickness of a member (or, a unit).

The expression “from above a plane” used herein may mean that it is viewed in the third direction DR3. The expression “on a section” used herein may mean that it is viewed in the first direction DR1 or the second direction DR2. Meanwhile, the directions indicated by the first to third directions DR1, DR2, and DR3 may be relative concepts and may be changed to different directions.

In an embodiment and referring to FIGS. 1A and 1B, the area of the display surface of the display module DM exposed by the display opening C-OP of the case CS may be adjusted depending on movement of the first case CS1 relative to the second case CS2. As the first case CS1 moves away from the second case CS2, the opening area of the display opening C-OP may increase in the first direction DR1.

In an embodiment, the display module DM may be a flexible display module and may be supported by a support layer disposed under the display module DM. When the first case CS1 moves in the first direction DR1, the support layer connected to the first case CS1 may also move together in the first direction DR1. Due to this, the display module DM disposed on the support layer may also move in the first direction DR1 depending on the movement of the first case CS1. As an end of the display module DM moves together with the first case CS1 in the first direction DR1, a portion of the display module DM received in the second case CS2 in the first mode may be exposed to the outside, and the display surface of the display module DM exposed through the display opening C-OP may be extended.

In an embodiment, FIG. 1A illustrates the display device DD in the first mode in which the first case CS1 is disposed closest to the second case CS2 in the first direction DR1, among operating states of the display device DD. In the first mode, one portion extending from one region of the display module DM exposed by the display opening C-OP may be folded with a certain curvature and may be received in the second case CS2. The first mode in which the display surface of the display module DM is set to a default size may be defined as a default mode.

In an embodiment, FIG. 1B illustrates the display device DD in the second mode in which the first case CS1 is disposed furthest from the second case CS2 in the first direction DR1, among the operating states of the display device DD. When the display device DD is in the second mode, the area of the display surface of the display module DM exposed by the display opening C-OP may be increased, as compared with when the display device DD is in the first mode. That is, the second mode in which the display surface is extended in the default mode may be defined as an extended mode.

In an embodiment, the first mode and the second mode of the display device DD may be determined depending on a sliding operation of the case CS and the display module DM. By switching the operating mode of the display device DD from the first mode to the second mode, a user may extend the display surface of the display device DD and may visually recognize an image through the extended display surface. In addition, by switching the operating mode of the display device DD from the second mode to the first mode, the user may reduce the display surface of the display device DD and may visually recognize an image through the reduced display surface. That is, by selecting one of the first mode and the second mode, the user may diversely adjust the area of the display surface of the display device DD exposed from the case CS.

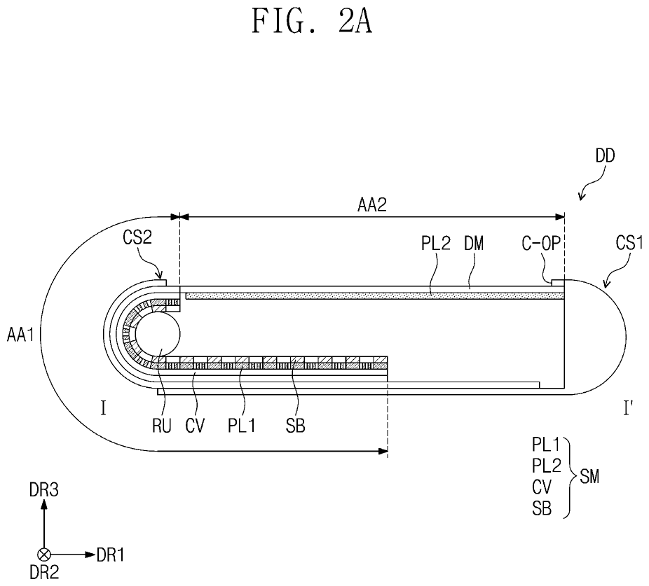

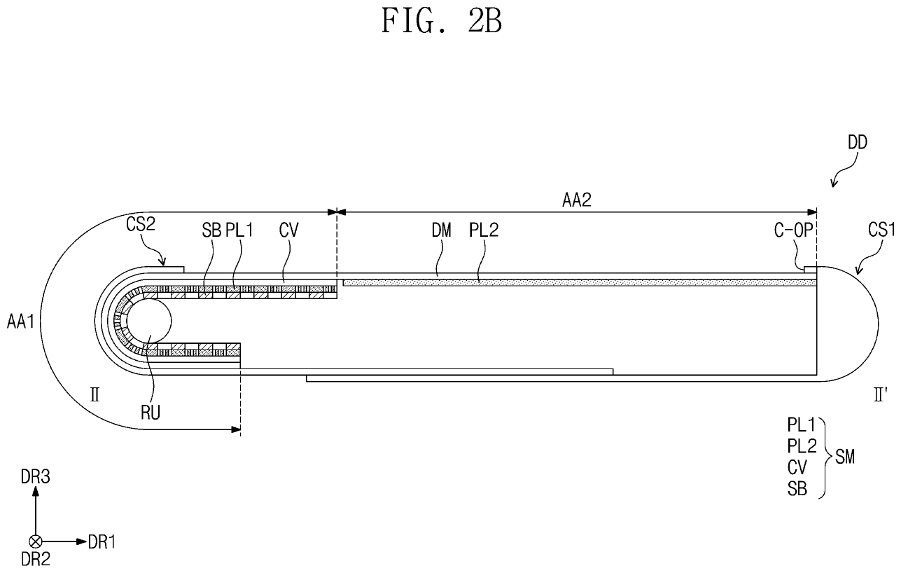

FIGS. 2A and 2B are sectional views of the display device according to an embodiment. FIG. 2A is a sectional view of the display device corresponding to line I-I′ of FIG. 1A. FIG. 2B is a sectional view of the display device corresponding to line II-II′ of FIG. 1B. FIG. 2A corresponds to a section of the display device DD in the first mode, and FIG. 2B corresponds to a section of the display device DD in the second mode.

In an embodiment and referring to FIGS. 2A and 2B, the display device DD may include the case CS, the display module DM accommodated in the case CS, a rotation unit RU, and a support module SM. The support module SM may be disposed under the display module DM and may support the display module DM. The support module SM may include a cover member CV, a first support layer PL1, a second support layer PL2, and support bars SB.

In an embodiment, the display module DM may include a first region AA1 and a second region AA2 extending from the first region AA1 in the first direction DR1. The first region AA1 may be a region supported by the cover member CV and the first support layer PL1, and the second region AA2 may be a region supported by the second support layer PL2.

In an embodiment and referring to FIG. 2A, in the first mode, the display surface of the display module DM that corresponds to the second region AA2 may be exposed to the outside. In the first mode, the second region AA2 may be directed parallel to the first direction DR1 and the second direction DR2 and may be defined as a planar region. A portion of the first region AA1 may be folded such that an end that is spaced apart from the second region AA2 overlaps the second region AA2 in the third direction DR3. The first region AA1 may be defined as a folding region. In the first mode, at least a portion of the first region AA1 may not be exposed to the outside. As illustrated in FIG. 2A, in the first mode, only a portion of the first region AA1 disposed adjacent to the second region AA2 may be exposed to the outside. Meanwhile, the expression “one region/portion corresponds to another region/portion” as used herein means that the regions/portions overlap each other and is not limited to having the same area.

In an embodiment, the rotation unit RU may be received in the second case CS2. The rotation unit RU may be rotated about a rotational axis that is directed in a direction parallel to one direction. FIGS. 2A and 2B illustrate the rotation unit RU rotatable about a rotational axis that is directed in a direction parallel to the second direction DR2. The rotation unit RU may be coupled to the second case CS2 and may rotate about the rotational axis depending on a sliding operation in which the first case CS1 moves away from or toward the second case CS2.

In an embodiment, as the first case CS1 of FIG. 2A moves away from the second case CS2 in the first direction DR1, the operating mode of the display device DD may be switched from the first mode to the second mode illustrated in FIG. 2B. When the operating mode of the display device DD is switched from the first mode to the second mode, an end of the second region AA2 of the display module DM that is spaced apart from the first region AA1 and fixedly coupled to the first case CS1 may move together depending on the movement of the first case CS1. In this case, the end of the first region AA1 of the display module DM that is spaced apart from the second region AA2 may move in a direction opposite to the direction in which the end of the second region AA2 coupled to the first case CS1 moves.

In an embodiment, a portion of the first region AA1 of the display module DM, and portions of the cover member CV, the first support layer PL1, and the support bars SB that support the first region AA1 of the display module DM may be disposed on a curved surface of the rotation unit RU and may be folded with a certain curvature. When the operating mode of the display device DD is switched from the first mode to the second mode, the first region AA1 of the display module DM, the cover member CV, the first support layer PL1, and the support bars SB may move along the curved surface of the rotation unit RU as the display module DM moves. In some embodiments, in the first mode, a portion of the display surface corresponding to the first region AA1 may be exposed to the outside, and when the operating mode of the display device DD is switched from the first mode to the second mode, the area by which the first region AA1 is exposed to the outside by the display opening C-OP may be increased. Meanwhile, in the first mode, the display surface corresponding to the first region AA1 may not be exposed to the outside.

In an embodiment, the support module SM supporting the first region AA1 folded along the curved surface of the rotation unit RU in the first mode and the second mode and the support module SM supporting the second region AA2 and remaining flat in the first mode and the second mode may include different components because required mechanical characteristics are different from each other. For example, a part of the support module SM supporting the first region AA1 of the display module DM may include the cover member CV, the first support layer PL1, and the support bars SB, and a part of the support module SM supporting the second region AA2 may include the second support layer PL2.

In an embodiment, because the support module SM has different components depending on the regions of the display module DM, a gap may exist between the components of the support module SM disposed side by side on the plane. For example, the cover member CV and the second support layer PL2 disposed side by side on the plane may be separate components distinguished from each other and may be spaced apart from each other in the first direction DR1. That is, a gap may exist between the cover member CV and the second support layer PL2.

Meanwhile, the display module DM, the cover member CV, the first support layer PL1, the second support layer PL2, and the support bars SB will be described below in detail with reference to the following drawings.

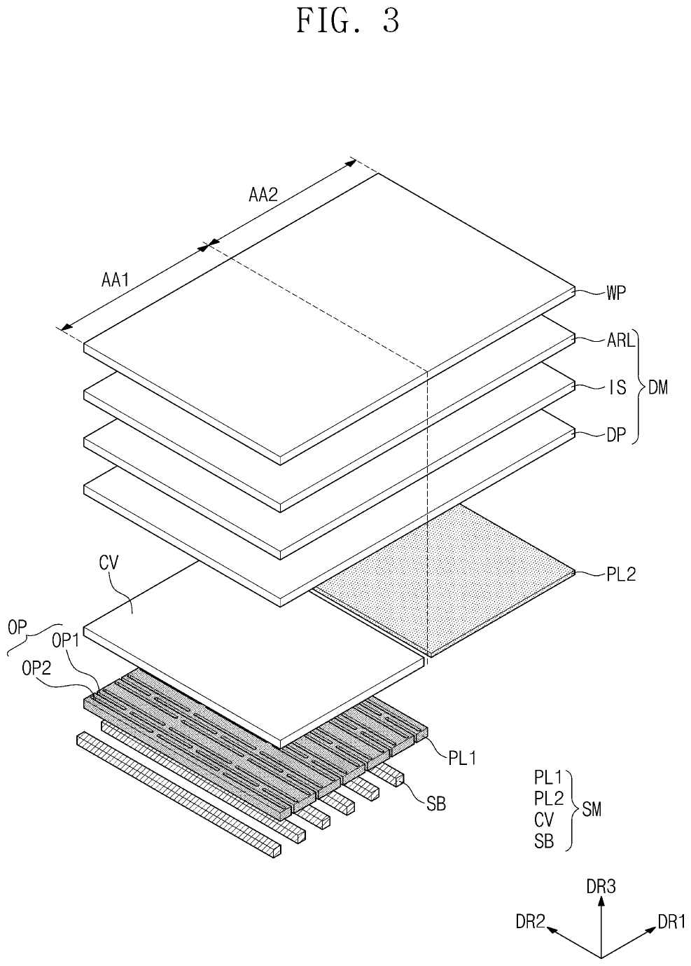

FIG. 3 is an exploded perspective view of the display device DD according to an embodiment. The above description may be identically applied to components illustrated in FIG. 3. The cover member CV, the first support layer PL1, the second support layer PL2, and the support bars SB will be mainly described with reference to FIG. 3.

In an embodiment and referring to FIG. 3, the display device DD may include a window WP and the display module DM. The display module DM may include a display panel DP, an input sensor IS, and an anti-reflective layer ARL.

In an embodiment, the window WP may be disposed on the display module DM and may cover the entire upper portion of the display module DM. The window WP may protect the display panel DP disposed under the window WP from external impacts and scratches. The window WP may be disposed on the anti-reflective layer ARL. An upper surface of the window WP may define the uppermost surface of the display device DD.

In an embodiment, the window WP may include an optically clear insulating material. For example, the window WP may include glass, sapphire, or a polymer. The window WP may have a single-layer structure or a multi-layer structure. The window WP may further include functional layers, such as an anti-fingerprint layer, a phase control layer, and a hard coating layer, which are disposed on an optically clear substrate.

In an embodiment, the input sensor IS may be directly disposed on the display panel DP. The display panel DP and the input sensor IS may be formed through a continuous process. When the input sensor IS is directly disposed on the display panel DP, this may mean that a third component is not disposed between the input sensor IS and the display panel DP. That is, a separate adhesive layer may not be disposed between the input sensor IS and the display panel DP.

In an embodiment, the anti-reflective layer ARL may be directly disposed on the input sensor IS. The anti-reflective layer ARL may decrease the reflectance of external light incident from outside the display device DD. The anti-reflective layer ARL may include at least one organic pattern. The organic pattern may include an organic material.

In an embodiment, the position of the input sensor IS and the position of the anti-reflective layer ARL may be interchanged with each other.

In an embodiment, the configuration of the display module DM is not limited thereto, and the display module DM may further include other functional layers disposed between the window WP and the display panel DP. For example, the display module DM may further include a protective layer disposed between the display panel DP and the window WP.

In an embodiment, the display panel DP may include a first region AA1 and a second region AA2. The first region AA1 and the second region AA2 of the display panel DP may correspond to the first region AA1 and the second region AA2 of the display module DM described above, and the description of the first region AA1 and the second region AA2 of the display module DM may be identically applied to the first region AA1 and the second region AA2 of the display panel DP. In FIG. 3, for convenience of description, the first region AA1 and the second region AA2 are represented on the upper surface of the window WP.

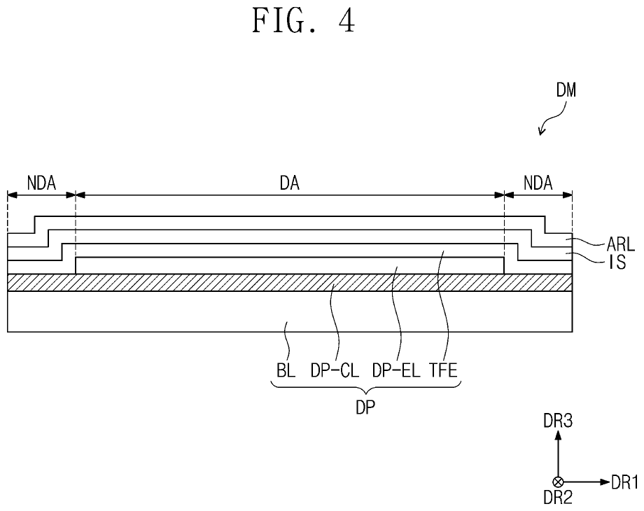

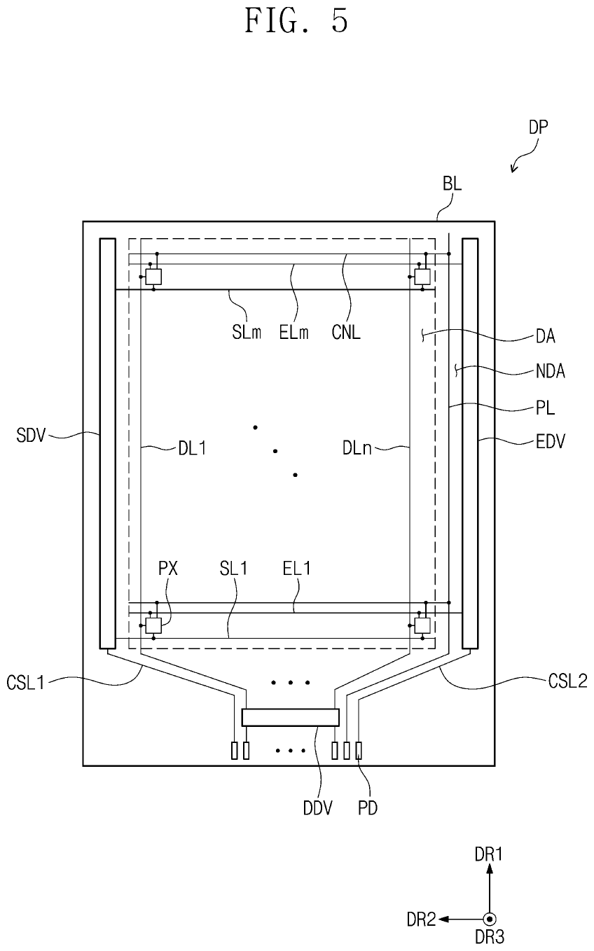

The display panel DP according to an embodiment may be an emissive display panel and is not particularly limited. For example, the display panel DP may be an organic light emitting display panel or an inorganic light emitting display panel. An emissive layer of the organic light emitting display panel may include an organic light emitting material. An emissive layer of the inorganic light emitting display panel may include an inorganic light emitting material such as quantum dots, quantum rods, or the like. Alternatively, an emissive layer of the display panel DP may include an extremely small light emitting element such as a micro-LED and/or a nano-LED. The display panel DP of one embodiment will be described below in detail with reference to FIGS. 4 and 5.

In an embodiment, the cover member CV may be disposed on a rear surface of the display panel DP. The cover member CV may overlap the first region AA1 of the display panel DP. The cover member CV may be parallel to the first direction DR1 and the second direction DR2 in an unfolded state. The cover member CV may protect the rear surface of the display panel DP that corresponds to the first region AA1 and may not overlap the second region AA2.

In an embodiment, the cover member CV may include a flexible elastic material. For example, the cover member CV may include a polymer material. The cover member CV may support the first region AA1 of the display panel DP that is folded with a certain curvature and may alleviate stress that is caused by folding. In addition, the cover member CV may prevent foreign matter from entering the display panel DP through openings OP defined in the first support layer PL1 disposed under the cover member CV. The cover member CV may not be disposed under the second region AA2 of the display panel DP because alleviating stress caused by folding is not required for the second region AA2 that is not folded even while the display device DD operates in the first mode and the second mode and an opening is not defined in the second support layer PL2 disposed under the display panel DP. Accordingly, a stacked structure of the display device DD corresponding to the second region AA2 may be simplified.

In an embodiment, the second support layer PL2 may be disposed on the rear surface of the display panel DP. The second support layer PL2 may overlap the second region AA2 of the display panel DP. The second support layer PL2 may have a plate shape that is directed parallel to the first direction DR1 and the second direction DR2. The second support layer PL2 may protect the rear surface of the display panel DP corresponding to the second region AA2 and may not overlap the first region AA1.

In an embodiment, the second support layer PL2 may include a material having a predetermined rigidity. For example, the second support layer PL2 may include stainless steel, aluminum or an alloy thereof. However, the material of the second support layer PL2 is not limited to the aforementioned examples. The second support layer PL2 may support the rear surface of the display panel DP such that the second region AA2 of the display panel DP remains flat in the first mode and the second mode. In addition, the second support layer PL2 may improve the impact resistance of the display panel DP.

In an embodiment, the cover member CV may include a material different from that of the second support layer PL2. The second support layer PL2 may have a higher modulus than the cover member CV. The cover member CV and the second support layer PL2 are not limited to any one embodiment as long as the cover member CV is capable of supporting the first region AA1 of the display panel DP and alleviating stress caused by folding and the second support layer PL2 is capable of supporting the second region AA2 of the display panel DP such that the second region AA2 remains flat.

In an embodiment, the cover member CV and the second support layer PL2 may be disposed side by side on the rear surface of the display panel DP. For example, one end of the cover member CV may face one end of the second support layer PL2 in the first direction DR1. The cover member CV may be spaced apart from the second support layer PL2 in the first direction DR1.

In an embodiment, the first support layer PL1 may be disposed under the cover member CV. The first support layer PL1 may overlap the first region AA1 of the display panel DP. The first support layer PL1 may be directed parallel to the first direction DR1 and the second direction DR2 in an unfolded state. The first support layer PL1 may not overlap the second region AA2. The first support layer PL1 may be spaced apart from the second support layer PL2 in the first direction DR1.

In an embodiment, the first support layer PL1 may include a material having a predetermined rigidity. Due to this, the first support layer PL1 may improve the impact resistance of the display panel DP corresponding to the first region AA1. For example, the first support layer PL1 may include stainless steel, aluminum or an alloy thereof. In an embodiment, the first support layer PL1 may include the same material as the second support layer PL2. However, the material of the first support layer PL1 is not limited to the aforementioned examples.

In an embodiment, the plurality of openings OP penetrating the first support layer PL1 may be defined in the first support layer PL1. The first support layer PL1 may be relatively easily folded by the openings OP. That is, the first support layer PL1 may be easily folded with a certain curvature by the openings OP at the same time as having rigidity.

In an embodiment, each of the openings OP may extend in the second direction DR2. That is, the widths of the openings OP in the second direction DR2 may be greater than the widths of the openings OP in the first direction DR1. The openings OP may be arranged in a lattice form. Accordingly, a lattice pattern may be formed in the first support layer PL1 by the openings OP.

In an embodiment, the openings OP may include first openings OP1 and second openings OP2 arranged so as to be staggered with respect to each other in a direction parallel to the first direction DR1. The first openings OP1 and the second openings OP2 may be arranged while forming rows in the second direction DR2. However, this is illustrative, and the plurality of openings OP according to an embodiment may all be arranged side by side in the second direction DR2 and are not limited to any one embodiment.

FIG. 3 illustrates an embodiment where the openings OP are divided into a plurality of groups that are arranged in the first direction DR1 where one group includes the first openings OP1 provided in a row and the second openings OP2 disposed on opposite sides of the first openings OP1. However, this is illustrative, and an arrangement of the openings OP and an interval between the openings OP may be diversely designed depending on the design of the display device DD and are not limited to any one embodiment.

In an embodiment, the support bars SB may be disposed under the first support layer PL1. Each of the support bars SB may extend in the second direction DR2. The support bars SB may be spaced apart from each other in the first direction DR1. The support bars SB may be provided as segmental bodies and may enable the first region AA1 of the display panel DP to be easily folded along the curved surface of the rotation unit RU (refer to FIG. 2A).

In an embodiment, the support bars SB may not overlap the openings OP of the first support layer PL1. Accordingly, the support bars SB may not degrade the folding characteristics of the first support layer PL1. However, embodiments are not necessarily limited thereto, and portions of the support bars SB may overlap the openings OP.

In an embodiment, the support bars SB may have a quadrangular prism shape extending in the second direction DR2. That is, each of the support bars SB may have a rectangular shape when viewed from a plane defined by the first direction DR1 and the third direction DR3. However, this is illustrative, and each of the support bars SB may have a cross-sectional shape different from a rectangular shape. For example, the cross-sections of the support bars SB may be formed in various shapes such as an inverted triangular shape, an inverted trapezoidal shape, and the like.

In an embodiment, the support bars SB may include metal having a predetermined rigidity. For example, the support bars SB may include metal such as aluminum, stainless steel, or invar, or may include carbon fiber. However, the material of the support bars SB is not limited to the aforementioned examples as long as the support bars SB are provided as segmental bodies and are capable of supporting the first region AA1 of the display panel DP.

FIG. 4 is a sectional view of the display module according to an embodiment. FIG. 5 is a plan view of the display panel according to an embodiment.

In an embodiment and referring to FIG. 4, the display module DM may include the display panel DP, the input sensor IS, and the anti-reflective layer ARL. The display panel DP may include a base layer BL, a circuit layer DP-CL, a light emitting element layer DP-EL, and an encapsulation layer TFE.

In an embodiment, the base layer BL may provide a base surface on which the circuit layer DP-CL is disposed. The base layer BL may be a flexible substrate that can be bent, folded, or rolled. The base layer BL may be a glass substrate, a metal substrate, or a polymer substrate. However, embodiments of the invention are not limited thereto, and the base layer BL may be an inorganic layer, an organic layer, or a composite layer.

In an embodiment, the base layer BL may have a multi-layer structure. For example, the base layer BL may include a first synthetic resin layer, an inorganic layer having a multi-layer structure or a single-layer structure, and a second synthetic resin layer disposed on the inorganic layer having the multi-layer structure or the single-layer structure. Each of the first and second synthetic resin layers may include a polyimide-based resin, but is not particularly limited.

In an embodiment, on a plane that is parallel to the first direction DR1 and the second direction DR2, the base layer BL may provide the base surface on which elements and lines of the display panel DP are disposed. The base layer BL may include a display region DA and a non-display region NDA. The display region DA may be a region on which pixels are disposed to display an image. The non-display region NDA may be a region that is disposed adjacent to the display region DA and on which an image is not displayed. The non-display region NDA may be a region on which lines connected to the pixels to transfer drive signals to the pixels are disposed.

In an embodiment, the circuit layer DP-CL may be disposed on the base layer BL. The circuit layer DP-CL may include a plurality of insulating layers, a semiconductor pattern, a conductive pattern, and a signal line.

In an embodiment, the light emitting element layer DP-EL may be disposed on the circuit layer DP-CL. The light emitting element layer DP-EL may include at least one light emitting element disposed to overlap the display region DA. For example, the light emitting element may include an organic light emitting material, an inorganic light emitting material, an organic-inorganic light emitting material, a quantum dot, a quantum rod, a micro-LED, or a nano-LED.

In an embodiment, the encapsulation layer TFE may be disposed on the light emitting element layer DP-EL. The encapsulation layer TFE may protect the light emitting element layer DP-EL from foreign matter such as moisture, oxygen, and dust particles. The encapsulation layer TFE may include at least one inorganic layer. The encapsulation layer TFE may include a stacked structure of an inorganic layer/an organic layer/an inorganic layer.

In an embodiment, the input sensor IS may be directly disposed on the display panel DP. The display panel DP and the input sensor IS may be formed through a continuous process.

In an embodiment, the anti-reflective layer ARL may be directly disposed on the input sensor IS. The anti-reflective layer ARL may decrease the reflectance of external light incident from outside the display device DD. The anti-reflective layer ARL includes at least one organic pattern. The organic pattern may include an organic material. In an embodiment, the position of the input sensor IS and the position of the anti-reflective layer ARL may be interchanged with each other.

In an embodiment and referring to FIG. 5, the display panel DP may include the base layer BL, a plurality of pixels PX, a plurality of signal lines SL1 to SLm, DL1 to DLn, EL1 to ELm, CSL1, CSL2, PL, and CNL electrically connected to the pixels PX, a scan driver SDV, a data driver DDV, and an emission driver EDV.

In an embodiment, each of the pixels PX may include a light emitting element and a pixel drive circuit that includes a plurality of transistors (e.g., a switching transistor, a drive transistor, and the like) and at least one capacitor that are connected to the light emitting element.

In an embodiment, the pixels PX may be disposed on the display region DA. Each of the pixels PX may emit light in response to an electrical signal applied to the pixel PX. However, some of the pixels PX may include a thin film transistor disposed on the non-display region NDA and are not limited to any one embodiment.

In an embodiment, the scan driver SDV, the data driver DDV, and the emission driver EDV may be disposed on the non-display region NDA. However, without being limited thereto, at least one of the scan driver SDV, the data driver DDV, and the emission driver EDV may be disposed on the display region DA. Due to this, the area of the non-display region NDA may be decreased.

In an embodiment, the data driver DDV may be provided in the form of an integrated circuit chip defined as a driver chip and may be mounted on the non-display region NDA of the display panel DP. However, without being limited thereto, the data driver DDV may be mounted on a separate flexible circuit board connected to the display panel DP and may be electrically connected to the display panel DP.

In an embodiment, the signal lines SL1 to SLm, DL1 to DLn, EL1 to ELm, CSL1, CSL2, PL, and CNL may include the scan lines SL1 to SLm, the data lines DL1 to DLn, the emission lines EL1 to ELm, the first and second control lines CSL1 and CSL2, the power line PL, and the connecting lines CNL. Here, “m” and “n” are natural numbers.

In an embodiment, the data lines DL1 to DLn may be insulated from the scan lines SL1 to SLm and the emission lines EL1 to ELm and may cross the scan lines SL1 to SLm and the emission lines EL1 to ELm. For example, the scan lines SL1 to SLm may extend in the second direction DR2 and may be connected to the scan driver SDV. The data lines DL1 to DLn may extend in the first direction DR1 and may be connected to the data driver DDV. The emission lines EL1 to ELm may extend in the second direction DR2 and may be connected to the emission driver EDV.

In an embodiment, the power line PL may extend in the first direction DR1 and may be disposed on the non-display region NDA. In an embodiment, the power line PL may be disposed between the display region DA and the emission driver EDV. However, the position of the power line PL is not limited thereto.

In an embodiment, the connecting lines CNL may extend in the second direction DR2. The connecting lines CNL may be arranged in the first direction DR1 and may be connected to the power line PL and the pixels PX. Each of the connecting lines CNL may be disposed on a layer different from the layer on which the power line PL is disposed and may be electrically connected with the power line PL through a contact hole. However, without being limited thereto, the connecting lines CNL may be integrally formed with the power line PL on the same layer. A power voltage may be applied to the pixels PX through the power line PL and the connecting lines CNL connected with each other.

In an embodiment, the first control line CSL1 may be connected to the scan driver SDV. The second control line CSL2 may be connected to the emission driver EDV.

In an embodiment, pads PD may be disposed adjacent to a lower end of the non-display region NDA. The pads PD may be disposed closer to the lower end of the display panel DP than the data driver DDV. The pads PD may be spaced apart from each other in the second direction DR2. The pads PD may be portions to which a circuit board that provides signals to control operations of the scan driver SDV, the data driver DDV, and the emission driver EDV of the display panel DP is connected.

In an embodiment, each of the pads PD may be connected to a corresponding signal line among the signal lines. The power line PL and the first and second control lines CSL1 and CSL2 may be connected to corresponding pads PD. The data lines DL1 to DLn may be electrically connected to corresponding pads PD through the data driver DDV.

In an embodiment, the scan driver SDV may generate scan signals in response to a scan control signal. The scan signals may be applied to the pixels PX through the scan lines SL1 to SLm. The data driver DDV may generate data voltages corresponding to image signals in response to a data control signal. The data voltages may be applied to the pixels PX through the data lines DL1 to DLn. The emission driver EDV may generate emission signals in response to an emission control signal. The emission signals may be applied to the pixels PX through the emission lines EL1 to ELm.

In an embodiment, the pixels PX may receive the data voltages in response to the scan signals. The pixels PX may display an image by emitting light having luminance corresponding to the data voltages in response to the emission signals. The light emission time of the pixels PX may be controlled by the emission signals. Accordingly, the display panel DP may output the image through the display region DA by the pixels PX.

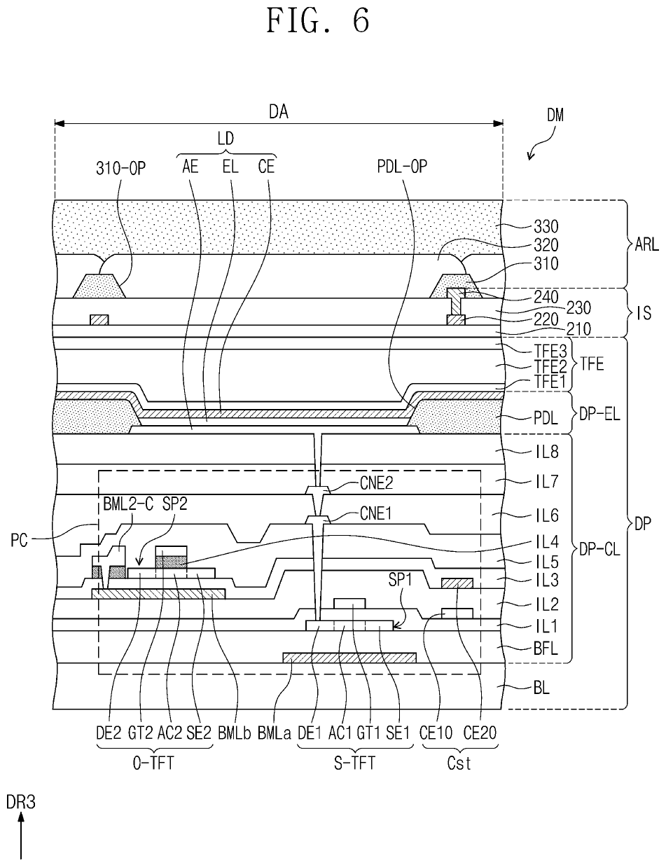

FIG. 6 is a sectional view of a portion of the display module according to an embodiment. In FIG. 6, a portion of the display module DM of the embodiment illustrated in FIG. 4 is illustrated in more detail. Specifically, components corresponding to one pixel of the display module DM of one embodiment are illustrated in more detail in FIG. 6.

In an embodiment, one light emitting element LD and a silicon transistor S-TFT and an oxide transistor O-TFT of a pixel circuit PC are illustrated in FIG. 6. At least one of a plurality of transistors included in the pixel circuit PC may be an oxide transistor O-TFT, and the remaining transistors may be silicon transistors S-TFT.

In an embodiment, a buffer layer BFL may be disposed on the base layer BL. The buffer layer BFL may prevent diffusion of metal atoms or impurities from the base layer BL to a first semiconductor pattern SP1 disposed on the buffer layer BFL. The first semiconductor pattern SP1 includes an active region AC1 of the silicon transistor S-TFT. The buffer layer BFL may adjust the speed at which heat is provided during a crystallization process for forming the first semiconductor pattern SCP1, thereby enabling the first semiconductor pattern SP1 to be uniformly formed.

In an embodiment, a first rear metal layer BMLa may be disposed under the silicon transistor S-TFT, and a second rear metal layer BMLb may be disposed under the oxide transistor O-TFT. The first and second rear metal layers BMLa and BM1b may be disposed to overlap the pixel circuit PC. The first and second rear metal layers BMLa and BM1b may block external light from reaching the pixel circuit PC.

In an embodiment, the first rear metal layer BMLa may be disposed to correspond to at least a partial region of the pixel circuit PC. The first rear metal layer BMLa may be disposed to overlap a drive transistor implemented with the silicon transistor S-TFT.

In an embodiment, the first rear metal layer BMLa may be disposed between the base layer BL and the buffer layer BFL. In an embodiment, an inorganic barrier layer may be additionally disposed between the first rear metal layer BMLa and the buffer layer BFL. The first rear metal layer BMLa may be connected with an electrode or a line and may receive a constant voltage or a signal from the electrode or the line. According to an embodiment, the first rear metal layer BMLa may be a floating electrode isolated from another electrode or line.

In an embodiment, the second rear metal layer BMLb may be disposed to correspond to a lower portion of the oxide transistor O-TFT. The second rear metal layer BMLb may be disposed between a second insulating layer IL2 and a third insulating layer IL3. The second rear metal layer BMLb may be disposed in the same layer as a second electrode CE20 of a storage capacitor Cst. The second rear metal layer BMLb may be connected with a contact electrode BML2-C and may receive a constant voltage or a signal. The contact electrode BML2-C may be disposed in the same layer as a gate GT2 of the oxide transistor O-TFT.

In an embodiment, each of the first rear metal layer BMLa and the second rear metal layer BMLb may include reflective metal. For example, each of the first rear metal layer BMLa and the second rear metal layer BMLb may include silver (Ag), an alloy containing silver (Ag), molybdenum (Mo), an alloy containing molybdenum, aluminum (Al), an alloy containing aluminum, aluminum nitride (AlN), tungsten (W), tungsten nitride (WN), copper (Cu), and p+ doped amorphous silicon. The first rear metal layer BMLa and the second rear metal layer BMLb may include the same material, or may include different materials.

Although not separately illustrated, the second rear metal layer BMLb may be omitted according to an embodiment. In an embodiment, the first rear metal layer BMLa may extend to below the oxide transistor O-TFT and may block light incident toward the lower portion of the oxide transistor O-TFT.

In an embodiment, the first semiconductor pattern SP1 may be disposed on the buffer layer BFL. The first semiconductor pattern SP1 may include a silicon semiconductor. For example, the silicon semiconductor may include amorphous silicon or polycrystalline silicon. For example, the first semiconductor pattern SP1 may include low-temperature polycrystalline silicon.

According to an embodiment, FIG. 6 illustrates only a portion of the first semiconductor pattern SP1 disposed on the buffer layer BFL, and the first semiconductor pattern SP1 may be additionally disposed in another region. The first semiconductor pattern SP1 may be arranged across the pixels according to a specific rule. The first semiconductor pattern SP1 may have different electrical properties depending on whether the first semiconductor pattern SP1 is doped or not. The first semiconductor pattern SP1 may include a first region having a high conductivity and a second region having a low conductivity. The first region may be doped with an N-type dopant or a P-type dopant. A P-type transistor may include a doped region that is doped with a P-type dopant, and an N-type transistor may include a doped region that is doped with an N-type dopant. The second region may be an un-doped region or may be a region more lightly doped than the first region.

In an embodiment, the conductivity of the first region may be higher than the conductivity of the second region, and the first region may substantially serve as an electrode or a signal line. The second region may substantially correspond to an active region (or, a channel) of the transistor. In other words, one portion of the first semiconductor pattern SP1 may be an active region of the transistor, another portion may be a source or a drain of the transistor, and the other portion may be a connecting electrode or a connecting signal line.

In an embodiment, a source region (or, a source) SE1, the active region (or, the channel) AC1, and a drain region (or, a drain) DE1 of the silicon transistor S-TFT may be formed from the first semiconductor pattern SP1. The source region SE1 and the drain region DE1 may extend from the active region AC1 in opposite directions on the section.

In an embodiment, a first insulating layer IL1 may be disposed on the buffer layer BFL. The first insulating layer IL1 may commonly overlap the plurality of pixels and may cover the first semiconductor pattern SP1. The first insulating layer IL1 may be an inorganic layer and/or an organic layer and may have a single-layer structure or a multi-layer structure. The first insulating layer IL1 may include at least one of aluminum oxide, titanium oxide, silicon oxide, silicon nitride, silicon oxy-nitride, zirconium oxide, and hafnium oxide. In an embodiment, the first insulating layer IL1 may be a single silicon oxide layer. Not only the first insulating layer IL1 but also insulating layers of the circuit layer DP-CL, which will be described below, may be inorganic layers and/or organic layers and may have a single-layer structure or a multi-layer structure. The inorganic layers may include at least one of the aforementioned materials but are not limited thereto.

In an embodiment, a gate GT1 of the silicon transistor S-TFT is disposed on the first insulating layer IL1. The gate GT1 may be a portion of a metal pattern. The gate GT1 overlaps the active region AC1. The gate GT1 may function as a mask in a process of doping the first semiconductor pattern SP1. The gate GT1 may include titanium (Ti), silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), indium tin oxide (ITO), or indium zinc oxide (IZO), but is not particularly limited thereto.

In an embodiment, the second insulating layer IL2 may be disposed on the first insulating layer IL1 and may cover the gate GT1. The third insulating layer IL3 may be disposed on the second insulating layer IL2. The second electrode CE20 of the storage capacitor Cst may be disposed between the second insulating layer IL2 and the third insulating layer IL3. Furthermore, a first electrode CE10 of the storage capacitor Cst may be disposed between the first insulating layer IL1 and the second insulating layer IL2.

In an embodiment, a second semiconductor pattern SP2 may be disposed on the third insulating layer IL3. The second semiconductor pattern SP2 may include an active region AC2 of the oxide transistor O-TFT that will be described below. The second semiconductor pattern SP2 may include an oxide semiconductor. The second semiconductor pattern SP2 may include transparent conductive oxide (TCO) such as indium tin oxide (ITO), indium zinc oxide (IZO), indium gallium zinc oxide (IGZO), zinc oxide (ZnOx), or indium oxide (In₂O₃).

In an embodiment, the oxide semiconductor may include a plurality of regions depending on whether the transparent conductive oxide is reduced. The region where the transparent conductive oxide is reduced (hereinafter, referred to as the reduced region) has a higher conductivity than the region where the transparent conductive oxide is not reduced (hereinafter, referred to as the non-reduced region). The reduced region substantially serves as a source/drain of the transistor or a signal line. The non-reduced region substantially corresponds to a semiconductor region (or, an active region or a channel) of the transistor. In other words, one partial region of the second semiconductor pattern SP2 may be a semiconductor region of the transistor, another partial region may be a source region/drain region of the transistor, and the other partial region may be a signal transmission region.

In an embodiment, a source region (or, a source) SE2, the active region (or, the channel) AC2, and a drain region (or, a drain) DE2 of the oxide transistor O-TFT may be formed from the second semiconductor pattern SP2. The source regions SE2 and the drain regions DE2 may extend from the active regions AC2 in opposite directions on the section.

In an embodiment, a fourth insulating layer IL4 may be disposed on the third insulating layer IL3. As illustrated in FIG. 6, the fourth insulating layer IL4 may be an insulating pattern that overlaps the gate GT2 of the oxide transistor O-TFT and that is exposed by the source region SE2 and the drain region DE2 of the oxide transistor O-TFT. As illustrated in FIG. 6, the fourth insulating layer IL4 may cover the second semiconductor pattern SP2.

In an embodiment and as illustrated in FIG. 6, the gate GT2 of the oxide transistor O-TFT is disposed on the fourth insulating layer IL4. The gate GT2 of the oxide transistor O-TFT may be a portion of a metal pattern. The gate GT2 of the oxide transistor O-TFT overlaps the active region AC2.

In an embodiment, a fifth insulating layer IL5 may be disposed on the fourth insulating layer IL4 and may cover the gate GT2. A first connecting electrode CNE1 may be disposed on the fifth insulating layer IL5. The first connecting electrode CNE1 may be connected to the drain region DE1 of the silicon transistor S-TFT through a contact hole penetrating the first insulating layer IL1, second insulating layer IL2, third insulating layer IL3, fourth insulating layer IL4 and fifth insulating layer IL5.

In an embodiment, a sixth insulating layer IL6 may be disposed on the fifth insulating layer IL5. A second connecting electrode CNE2 may be disposed on the sixth insulating layer IL6. The second connecting electrode CNE2 may be connected to the first connecting electrode CNE1 through a contact hole penetrating the sixth insulating layer IL6. A seventh insulating layer IL7 may be disposed on the sixth insulating layer IL6 and may cover the second connecting electrode CNE2. An eighth insulating layer IL8 may be disposed on the seventh insulating layer IL7.

In an embodiment, each of the sixth insulating layer IL6, the seventh insulating layer IL7, and the eighth insulating layer IL8 may be an organic layer. For example, each of the sixth insulating layer IL6, the seventh insulating layer IL7, and the eighth insulating layer IL8 may include a general purpose polymer, such as benzocyclobutene (BCB), polyimide, hexamethyldisiloxane (HMDSO), Polymethylmethacrylate (PMMA), or Polystyrene (PS), a polymer derivative having a phenolic group, an acrylate-based polymer, an imide-based polymer, an aryl ether-based polymer, an amide-based polymer, a fluorine-based polymer, a p-xylene-based polymer, a vinyl alcohol-based polymer, or a blend thereof.

In an embodiment, the light emitting element LD may include a first electrode AE, an emissive layer EL, and a second electrode CE. The second electrode CE may be commonly provided on a plurality of light emitting elements.

In an embodiment, the first electrode AE of the light emitting element LD may be disposed on the eighth insulating layer IL8. The first electrode AE of the light emitting element LD may be a (semi-) transmissive electrode or a reflective electrode. According to an embodiment, the first electrode AE of the light emitting element LD may include a reflective layer formed of Ag, Mg, Al, Pt, Pd, Au, Ni, Nd, Ir, Cr, or a compound thereof and a transparent or translucent electrode layer formed on the reflective layer. The transparent or translucent electrode layer may include at least one selected from the group consisting of indium tin oxide (ITO), indium zinc oxide (IZO), indium gallium zinc oxide (IGZO), zinc oxide (ZnO), or indium oxide (In₂O₃) and aluminum-doped zinc oxide (AZO). For example, the first electrode AE of the light emitting element LD may include a stacked structure of ITO/Ag/ITO.

In an embodiment, a pixel defining layer PDL may be disposed on the eighth insulating layer IL8. The pixel defining layer PDL may have a property of absorbing light. For example, the pixel defining layer PDL may be black in color. The pixel defining layer PDL may include a black coloring agent. The black coloring agent may include a black dye or a black pigment. The black coloring agent may include carbon black, metal such as chromium, or oxide thereof. The pixel defining layer PDL may correspond to a light blocking pattern having light blocking characteristics.

In an embodiment, the pixel defining layer PDL may cover a portion of the first electrode AE of the light emitting element LD. For example, an opening PDL-OP for exposing a portion of the first electrode AE of the light emitting element LD may be defined in the pixel defining layer PDL. The pixel defining layer PDL may increase the distance between the periphery of the first electrode AE of the light emitting element LD and the second electrode CE thereof. Accordingly, the pixel defining layer PDL may serve to prevent an arc from occurring at the periphery of the first electrode AE. A pixel region may be defined by the opening PDL-OP formed in the pixel defining layer PDL.

Although not illustrated, in an embodiment, a hole control layer may be disposed between the first electrode AE and the emissive layer EL. The hole control layer may include a hole transport layer and may further include a hole injection layer. In an embodiment, an electron control layer may be disposed between the emissive layer EL and the second electrode CE. The electron control layer may include an electron transport layer and may further include an electron injection layer. The hole control layer and the electron control layer may be commonly formed for the plurality of pixels PX (refer to FIG. 5) by using an open mask.

In an embodiment, the encapsulation layer TFE may be disposed on the light emitting element layer DP-EL. The encapsulation layer TFE may include an inorganic encapsulation layer TFE1, an organic encapsulation layer TFE2, and an inorganic encapsulation layer TFE3 sequentially stacked one above another. However, layers constituting the encapsulation layer TFE are not limited thereto.

In an embodiment, the inorganic encapsulation layers TFE1 and TFE3 may protect the light emitting element layer DP-EL from moisture and oxygen, and the organic encapsulation layer TFE2 may protect the light emitting element layer DP-EL from foreign matter such as dust particles. The inorganic encapsulation layers TFE1 and TFE3 may include a silicon nitride layer, a silicon oxy-nitride layer, a silicon oxide layer, a titanium oxide layer, or an aluminum oxide layer. The organic encapsulation layer TFE2 may include an acrylate-based organic layer, but is not limited thereto.

In an embodiment, the input sensor IS may be disposed on the display panel DP. The input sensor IS may be referred to as a sensor, an input sensing layer, or an input sensing panel. The input sensor IS may include a sensor base layer 210, a first conductive layer 220, a sensing insulation layer 230, and a second conductive layer 240.

In an embodiment, the sensor base layer 210 may be directly disposed on the display panel DP. The sensor base layer 210 may be an inorganic layer including at least one of silicon nitride, silicon oxy-nitride, and silicon oxide. Alternatively, the sensor base layer 210 may be an organic layer including an epoxy resin, an acrylic resin, or an imide-based resin. The sensor base layer 210 may have a single-layer structure, or may have a multi-layer structure stacked in the third direction DR3.

In an embodiment, each of the first conductive layer 220 and the second conductive layer 240 may have a single-layer structure, or may have a multi-layer structure stacked in the third direction DR3. The first conductive layer 220 and the second conductive layer 240 may include conductive lines that define sensing electrodes having a mesh shape. The conductive lines may not overlap the opening PDL-OP and may overlap the pixel defining layer PDL.

In an embodiment, the conductive layer having a single-layer structure may include a metal layer or a transparent conductive layer. The metal layer may include molybdenum, silver, titanium, copper, aluminum, or an alloy thereof. The transparent conductive layer may include transparent conductive oxide such as indium tin oxide (ITO), indium zinc oxide (IZO), zinc oxide (ZnO), indium zinc tin oxide (IZTO), or the like. In addition, the transparent conductive layer may include a conductive polymer such as PEDOT, a metal nano-wire, or graphene.

In an embodiment, the conductive layer having a multi-layer structure may include metal layers sequentially stacked one above another. The metal layers may have, for example, a three-layer structure of titanium/aluminum/titanium. The conductive layer having a multi-layer structure may include at least one metal layer and at least one transparent conductive layer.

In an embodiment, the sensing insulation layer 230 may be disposed between the first conductive layer 220 and the second conductive layer 240. The sensing insulation layer 230 may include an inorganic film. The inorganic film may include at least one of aluminum oxide, titanium oxide, silicon oxide, silicon nitride, silicon oxy-nitride, zirconium oxide, and hafnium oxide.

In another embodiment, the sensing insulation layer 230 may include an organic film. The organic film may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyimide-based resin, a polyamide-based resin, and a perylene-based resin.

In an embodiment, the anti-reflective layer ARL may be disposed on the input sensor IS. The anti-reflective layer ARL may include a black matrix 310, a plurality of color filters 320, and an overcoat layer 330.

In an embodiment, a material constituting the black matrix 310 is not particularly limited as long as it is a material that absorbs light. The black matrix 310 may be a layer having a black color. In an embodiment, the black matrix 310 may include a black coloring agent. The black coloring agent may include a black dye or a black pigment. The black coloring agent may include carbon black, metal such as chromium, or oxide thereof. The black matrix 310 may include a first organic material.

In an embodiment, the black matrix 310 may cover the second conductive layer 240 of the input sensor IS. The black matrix 310 may prevent reflection of external light by the second conductive layer 240. In a partial region of the display module DM, the black matrix 310 may be omitted. The transmittance of the region in which the black matrix 310 is omitted may be higher than that of another region.

In an embodiment, the black matrix 310 may have an opening 310-OP defined therein. The opening 310-OP may overlap the first electrode AE of the light emitting element LD. One of the plurality of color filters 320 may overlap the first electrode AE of the light emitting element LD. The one of the plurality of color filters 320 may cover the opening 310-OP. Each of the plurality of color filters 320 may make contact with the black matrix 310.

In an embodiment, each of the plurality of color filters 320 may be disposed to overlap an upper surface of the first electrode AE exposed by the opening PDL-OP defined in the pixel defining layer PDL. That is, the plurality of color filters 320 may be disposed to correspond to the respective pixel regions.

In an embodiment, each of the plurality of color filters 320 may transmit color light corresponding to the emission color of the corresponding pixel region. In an embodiment, each of the plurality of color filters 320 may be a red filter, a green filter, or a blue filter. Each of the plurality of color filters 320 may include a photosensitive polymer resin and a pigment or dye. Each of the plurality of color filters 320 may include a second organic material. Each of the plurality of color filters 320 may include a red pigment or dye, a green pigment or dye, or a blue pigment or dye in addition to the second organic material that is a base material.

In an embodiment, the overcoat layer 330 may cover the black matrix 310 and the plurality of color filters 320. The overcoat layer 330 may include an organic material and may provide a flat surface on an upper surface of the overcoat layer 330.

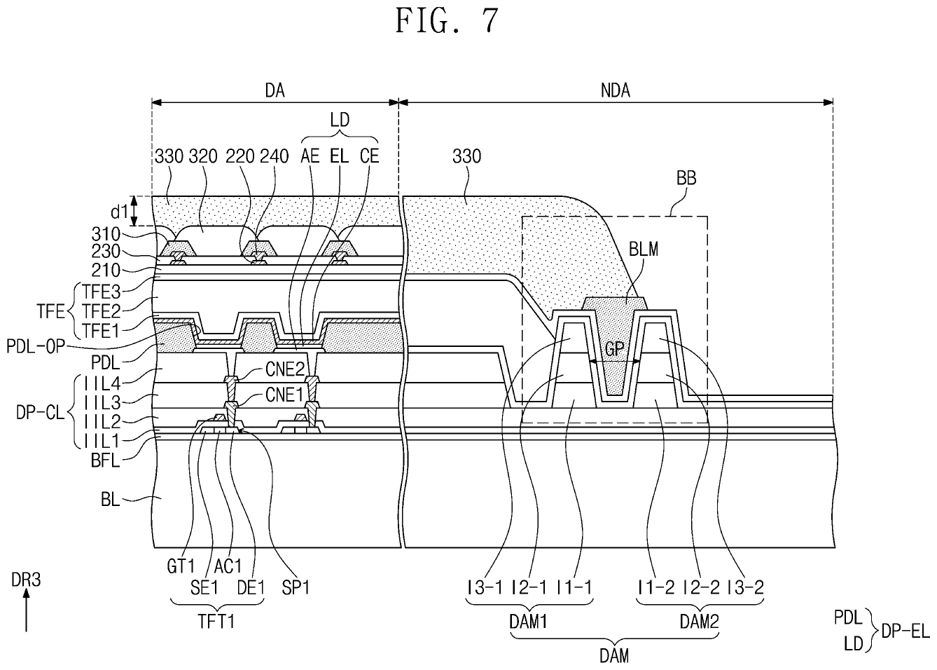

FIG. 7 is a sectional view of a portion of the display module according to an embodiment. FIG. 7 illustrates sections corresponding to a portion of the display region DA and a portion of the non-display region NDA around the display region DA in the display module DM of the embodiment illustrated in FIG. 4.

In an embodiment and referring to FIGS. 6 and 7 together, the buffer layer BFL may be disposed on the base layer BL.

In an embodiment, a first semiconductor pattern SP1 may be disposed on the buffer layer BFL. The first semiconductor pattern SP1 may include a silicon semiconductor. For example, the silicon semiconductor may include amorphous silicon or polycrystalline silicon. For example, the first semiconductor pattern SP1 may include low-temperature polycrystalline silicon. FIG. 7 illustrates only a portion of the first semiconductor pattern SP1 disposed on the buffer layer BFL, and the first semiconductor pattern SP1 may be additionally disposed in another region.

In an embodiment, a source region (or, a source) SE1, an active region (or, a channel) AC1, and a drain region (or, a drain) DE1 of a first transistor TFT1 may be formed from the first semiconductor pattern SP1. The source region SE1 and the drain region DE1 may extend from the active region AC1 in opposite directions on the section. A gate GT1 of the first transistor TFT1 is disposed on at least one of a plurality of insulating layers IIL1, IIL2, IIL3, and IIL4. The gate GT1 may be a portion of a metal pattern and may overlap the active region AC1.

In an embodiment, the circuit layer DP-CL may include the plurality of insulating layers IIL1, IIL2, IIL3, and IIL4 disposed on the buffer layer BFL, and each of the plurality of insulating layers IIL1, IIL2, IIL3, and IIL4 may correspond to one layer among the first to eighth insulating layers IL1 to IL8, respectively, illustrated in FIG. 6. The plurality of insulating layers IIL1, IIL2, IIL3, and IIL4 may be disposed on the first transistor TFT1 to cover the first transistor TFT1 and may be disposed to commonly overlap the plurality of pixels. Meanwhile, each of the plurality of insulating layers IIL1, IIL2, IIL3, and IIL4 may be an inorganic layer and/or an organic layer and may have a single-layer structure or a multi-layer structure. Each of the plurality of insulating layers IIL1, IIL2, IIL3, and IIL4 may include at least one of aluminum oxide, titanium oxide, silicon oxide, silicon nitride, silicon oxy-nitride, zirconium oxide, and hafnium oxide. In another embodiment, each of the plurality of insulating layers IIL1, IIL2, IIL3, and IIL4 may include a general purpose polymer, such as benzocyclobutene (BCB), polyimide, hexamethyldisiloxane (HMDSO), Polymethylmethacrylate (PMMA), or Polystyrene (PS), a polymer derivative having a phenolic group, an acrylate-based polymer, an imide-based polymer, an aryl ether-based polymer, an amide-based polymer, a fluorine-based polymer, a p-xylene-based polymer, a vinyl alcohol-based polymer, or a blend thereof.

In an embodiment, the circuit layer DP-CL may include a first connecting electrode CNE1 and a second connecting electrode CNE2, and each of the first connecting electrode CNE1 and the second connecting electrode CNE2 may be connected to the source regions SE1 or the drain region DE1 of the first transistor TFT1 through a contact hole penetrating at least one of the plurality of insulating layers IIL1, IIL2, IIL3, and IIL4.

In an embodiment, the light emitting element layer DP-EL is disposed on the circuit layer DP-CL. The light emitting element layer DP-EL includes at least one light emitting element LD. The light emitting element LD may include a first electrode AE, an emissive layer EL, and a second electrode CE. The second electrode CE may be commonly provided on a plurality of light emitting elements. The light emitting element layer DP-EL may include the pixel defining layer PDL, and the pixel defining layer PDL may cover a portion of the first electrode AE of the light emitting element LD. An opening PDL-OP for exposing a portion of the first electrode AE of the light emitting element LD may be defined in the pixel defining layer PDL.

In an embodiment, the encapsulation layer TFE may be disposed on the light emitting element layer DP-EL. The encapsulation layer TFE may include the inorganic encapsulation layer TFT1, the organic encapsulation layer TFE2, and the inorganic encapsulation layer TFE3 sequentially stacked one above another. However, layers constituting the encapsulation layer TFE are not limited thereto. The inorganic encapsulation layers TFE1 and TFE3 may protect the light emitting element layer DP-EL from moisture and oxygen, and the organic encapsulation layer TFE2 may protect the light emitting element layer DP-EL from foreign matter such as dust particles.

In an embodiment, the input sensor IS may be disposed on the display panel DP. The input sensor IS may be referred to as a sensor, an input sensing layer, or an input sensing panel. The input sensor IS may include the sensor base layer 210, the first conductive layer 220, the sensing insulation layer 230, and the second conductive layer 240.

In an embodiment, the anti-reflective layer ARL may be disposed on the input sensor IS. The anti-reflective layer ARL may include the black matrix 310, the plurality of color filters 320, and the overcoat layer 330.

In an embodiment, a material constituting the black matrix 310 is not particularly limited as long as it is a material that absorbs light. The black matrix 310 may be a layer having a black color. In an embodiment, the black matrix 310 may include a black coloring agent. The black coloring agent may include a black dye or a black pigment. The black coloring agent may include carbon black, metal such as chromium, or oxide thereof. The black matrix 310 may include the first organic material.

In an embodiment, the black matrix 310 may cover the second conductive layer 240 of the input sensor IS. The black matrix 310 may prevent reflection of external light by the second conductive layer 240. In a partial region of the display module DM, the black matrix 310 may be omitted. The transmittance of the region in which the black matrix 310 is omitted may be higher than that of another region.

In an embodiment, the black matrix 310 may have an opening 310-OP defined therein. The opening 310-OP may overlap the first electrode AE of the light emitting element LD. One of the plurality of color filters 320 may overlap the first electrode AE of the light emitting element LD. The one of the plurality of color filters 320 may cover the opening 310-OP. Each of the plurality of color filters 320 may make contact with the black matrix 310.

In an embodiment, each of the plurality of color filters 320 may be disposed to overlap an upper surface of the first electrode AE exposed by the opening PDL-OP defined in the pixel defining layer PDL. That is, the plurality of color filters 320 may be disposed to correspond to the respective pixel regions.

In an embodiment, each of the plurality of color filters 320 may transmit light having a specific wavelength. Each of the plurality of color filters 320 may transmit color light corresponding to the emission color of the corresponding pixel region. In an embodiment, each of the plurality of color filters 320 may be a red filter, a green filter, or a blue filter. Each of the plurality of color filters 320 may include a photosensitive polymer resin and a pigment or dye. Each of the plurality of color filters 320 may include the second organic material. Each of the plurality of color filters 320 may include a red pigment or dye, a green pigment or dye, or a blue pigment or dye in addition to the second organic material that is a base material.

In an embodiment, the overcoat layer 330 may cover the black matrix 310 and the plurality of color filters 320. The overcoat layer 330 may include an organic material and may provide a flat surface on the upper surface of the overcoat layer 330.

In an embodiment and referring to FIG. 7, the circuit layer DP-CL further includes a dam structure DAM overlapping the non-display region NDA. The dam structure DAM may be disposed on the base layer BL. The dam structure DAM may overlap the non-display region NDA and may not overlap the display region DA. The dam structure DAM may be disposed to surround the display region DA. The dam structure DAM may be disposed at the periphery of the display module DM and may prevent the organic encapsulation layer TFE2 from overflowing.

In an embodiment, the dam structure DAM may include a plurality of dams. The dam structure DAM may include a first dam DAM1 and a second dam DAM2. The first dam DAM1 and the second dam DAM2 may be sequentially arranged in a direction away from the display region DA. That is, the second dam DAM2 may be spaced farther away from the display region DA than the first dam DAM1, and the first dam DAM1 may be disposed between the region where the second dam DAM2 is disposed and the display region DA.

In an embodiment, the dam structure DAM may include a plurality of layers. In an embodiment, the dam structure DAM may include first to third layers. The first dam DAM1 may include a layer 1-1 I1-1, a layer 2-1 I2-1, and a layer 3-1 I3-1, and the second dam DAM2 may include a layer 1-2 I1-2, a layer 2-2 I2-2, and a layer 3-2 I3-2.

In an embodiment, the first dam DAM1 and the second dam DAM2 may have substantially the same height. Each of the first dam DAM1 and the second dam DAM2 may be disposed on at least one of the plurality of insulating layers IIL1, IIL2, IIL3, and IIL4 described above. In an embodiment, each of the first dam DAM1 and the second dam DAM2 may be disposed on the second insulating layer IIL2 among the plurality of insulating layers IIL1, IIL2, IIL3, and IIL4 described above.

In an embodiment, each of the first dam DAM1 and the second dam DAM2 may have a layer corresponding to at least one of the plurality of insulating layers IIL1, IIL2, IIL3, and IIL4 described above. Each of the first dam DAM1 and the second dam DAM2 may have a layer corresponding to the pixel defining layer PDL. In an embodiment, each of the first dam DAM1 and the second dam DAM2 may have a three-layer structure that includes layers corresponding to the third insulating layer IIL3 and the fourth insulating layer IIL4 disposed on the upper side among the plurality of insulating layers IIL1, IIL2, IIL3, and IIL4 and a layer corresponding to the pixel defining layer PDL. The layer 1-1 I1-1 and the layer 1-2 I1-2 may include a same material as the third insulating layer IIL3 and may be formed through a same process as the third insulating layer IIL3. The layer 2-1 I2-1 and the layer 2-2 I2-2 may include a same material as the fourth insulating layer IIL4 and may be formed through a same process as the fourth insulating layer IIL4. The layer 3-1 I3-1 and the layer 3-2 I3-2 may include a same material as the pixel defining layer PDL and may be formed through a same process as the pixel defining layer PDL.

In an embodiment, unlike those illustrated in FIG. 7, the first dam DAM1 and the second dam DAM2 may have different heights. In an embodiment, the first dam DAM1 may have a smaller height than the second dam DAM2. In this case, the layer 3-1 I3-1 may be omitted from the first dam DAM1, and the first dam DAM1 may have a two-layer structure.

In an embodiment, a separation space GP may be defined between the plurality of dams DAM1 and DAM2 included in the dam structure DAM. The separation space GP may be defined between the first dam DAM1 and the second dam DAM2 spaced apart from each other in one direction.

The display module DM in an embodiment includes a blocking member BLM overlapping at least a portion of the dam structure DAM on the plane. The blocking member BLM may be disposed on the dam structure DAM and may be included in the circuit layer DP-CL.

In an embodiment, the blocking member BLM includes the same material as at least one organic pattern included in the above-described anti-reflective layer ARL. In an embodiment, the blocking member BLM may be formed through a same process as the at least one organic pattern included in the anti-reflective layer ARL. An organic material provided in a process of forming the at least one organic pattern included in the anti-reflective layer ARL may be subjected to patterning to overlap at least a portion of the dam structure DAM to form the blocking member BLM. For example, at least a portion of the blocking member BLM may be disposed in the separation space GP defined between the plurality of dams DAM1 and DAM2 included in the dam structure DAM.

In an embodiment, the anti-reflective layer ARL may include the plurality of color filters 320 and the black matrix 310 as an organic pattern, and the blocking member BLM may include the same material as at least one of the black matrix 310 and the plurality of color filters 320 included in the anti-reflective layer ARL. For example, the blocking member BLM may include the same material as the black matrix 310.

In an embodiment, the overcoat layer 330 has a large thickness and overlaps at least a portion of the blocking member BLM on the plane. The overcoat layer 330 may completely overlap the display region DA and may also overlap a portion of the non-display region NDA. The overcoat layer 330 may make contact with the blocking member BLM. For example, the overcoat layer 330 may be disposed to make contact with the upper surface of the blocking member BLM.

In an embodiment, the thickness d1 of the overcoat layer 330 may range from about 10 micrometers to about 50 micrometers. For example, the thickness d1 of the overcoat layer 330 may range from about 10 micrometers to about 30 micrometers. Meanwhile, the thickness d1 of the overcoat layer 330 may be defined as the distance from the upper surfaces of the plurality of color filters 320 to the upper surface of the overcoat layer 330.

In an embodiment, when the thickness d1 of the overcoat layer 330 is less than about 10 micrometers, the display panel DP may have wavy lines, or may be cracked, due to tensile and compressive strains applied when the display device DD including the display module DM operates in the first mode and the second mode. When the thickness d1 of the overcoat layer 330 exceeds about 50 micrometers, the display module DM may be excessively thick. Due to this, the display device DD may have difficulty operating in the first mode and the second mode, and the total thickness of the display device DD may be increased.

In an embodiment, the overcoat layer 330 may be formed by an ink-jet process. The overcoat layer 330 may not be subjected to patterning by a photoresist process but may be formed to have a thickness of about 10 micrometers or more through an ink-jet process. Meanwhile, because the overcoat layer 330 is formed by an ink-jet process, the overcoat layer 330 may be formed to overlap not only the display region DA but also a portion of the non-display region NDA.

In an embodiment, because the overcoat layer 330 included in the anti-reflective layer ARL has a thickness of about 10 micrometers or more, tensile and compressive strains applied to the display panel DP when the display surface of the display device DD is extended may be effectively reduced, and thus defects such as wavy lines and cracks in the display panel DP may be prevented. More specifically, the display surface corresponding to the first region AA1 may be folded with a certain curvature while the display device DD operates in the first mode and the second mode, and therefore the display panel DP may have wavy lines, or may be cracked, by tensile and compressive strains caused by the folding. However, because the overcoat layer 330 included in the anti-reflective layer ARL has a thickness of about 10 micrometers or more, even though tensile and compressive stresses are applied to the first region of the display panel DP, the tensile and compressive stresses may be alleviated by the thick overcoat layer 330, and thus damage to the display panel DP may be prevented.

In an embodiment, when an ink-jet process is applied to form the overcoat layer 330 having a large thickness, it is difficult to specifically form the overcoat layer 330 only in the display region DA, and therefore the overcoat layer 330 is formed to overlap a portion of the non-display region NDA. Meanwhile, in the display device DD of one embodiment, by additionally forming the blocking member BLM overlapping the dam structure DAM in a process of forming the at least one organic pattern included in the anti-reflective layer ARL, the overcoat layer 330 may be prevented from overflowing outside the region in which the blocking member BLM is formed. Accordingly, the reliability and durability of the display module DM including the overcoat layer 330 and the display device DD may be improved.

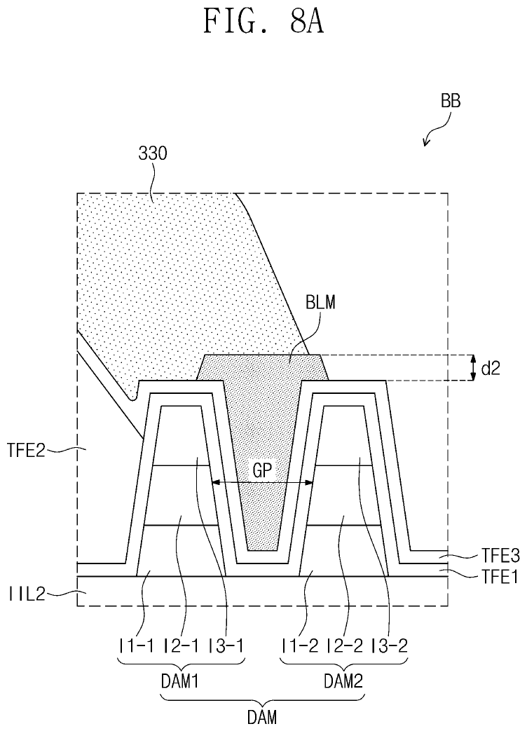

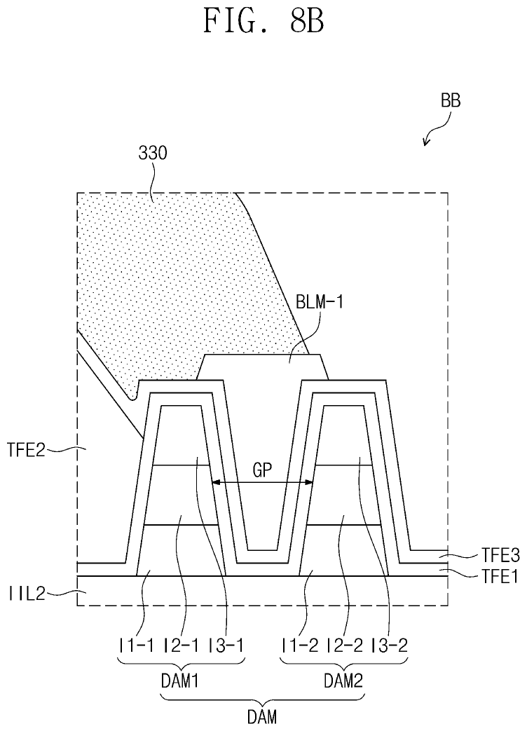

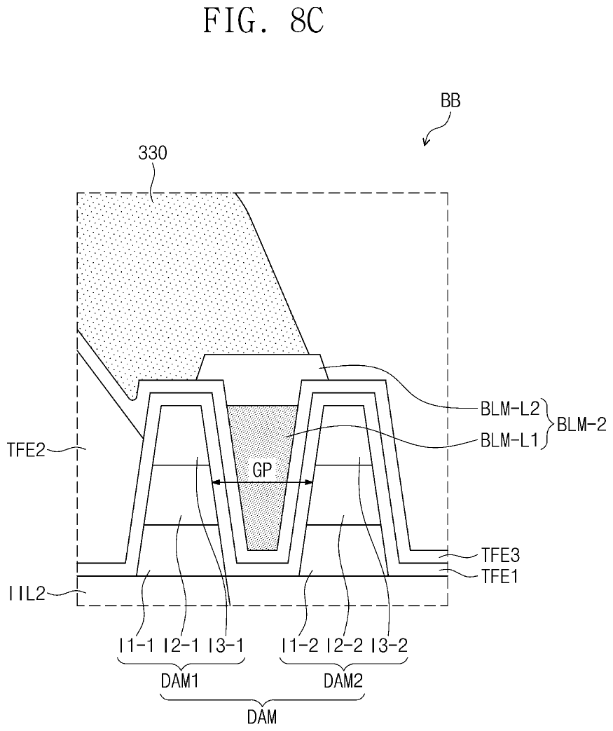

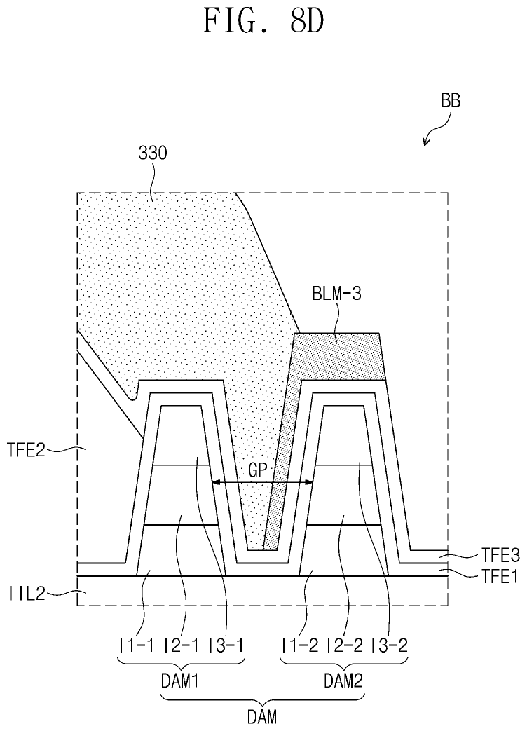

FIGS. 8A to 8D are enlarged sectional views of a portion of the display module, according to embodiments. FIGS. 8A to 8D are enlarged views of region BB of FIG. 7. That is, the shapes of the dam structure DAM, blocking members BLM, BLM-1, BLM-2, and BLM-3 overlapping the dam structure DAM, and the overcoat layer 330 overlapping the blocking members BLM, BLM-1, BLM-2, and BLM-3 on the section of the display module illustrated in FIG. 7 are illustrated in FIGS. 8A to 8D.

In an embodiment and referring to FIGS. 7, 8A, and 8B, the display module DM may include the dam structure DAM, and the dam structure DAM may include the first dam DAM1 and the second dam DAM2. The separation space GP may be defined between the plurality of dams DAM1 and DAM2. The blocking members BLM and BLM-1 may be disposed on the dam structure DAM. In particular, the blocking members BLM and BLM-1 may be disposed in the separation space GP defined between the first dam DAM1 and the second dam DAM2. Meanwhile, the blocking members BLM and BLM-1 may be disposed on the inorganic encapsulation layer TFE3 included in the encapsulation layer TFE.

In an embodiment, the blocking members BLM and BLM-1 include a same material as the at least one organic pattern included in the above-described anti-reflective layer ARL. In an embodiment, the blocking members BLM and BLM-1 may be formed through a same process as the at least one organic pattern included in the anti-reflective layer ARL. The organic material provided in the process of forming the at least one organic pattern included in the anti-reflective layer ARL may be subjected to patterning to overlap at least a portion of the dam structure DAM to form the blocking members BLM and BLM-1. For example, as illustrated in FIGS. 7 and 8A, the blocking member BLM and the black matrix 310 may include a same material. In another embodiment, as illustrated in FIG. 8B, the blocking member BLM-1 and the plurality of color filters 320 may include a same material. The blocking member BLM-1 and one of the plurality of color filters 320 may include a same material. For example, the plurality of color filters 320 may include a red filter, a green filter, and a blue filter, and the blocking member BLM-1 may include a same material as at least one of the red filter, the green filter, and the blue filter.

In an embodiment, the overcoat layer 330 overlaps at least a portion of the blocking member BLM on the plane. The overcoat layer 330 may make contact with the blocking member BLM. For example, the overcoat layer 330 may be disposed to make contact with the upper surface of the blocking member BLM. The overcoat layer 330 may also make contact with a portion of the side surface of the blocking member BLM.

In an embodiment and as illustrated in FIG. 8A, the blocking member BLM may have a shape protruding above the upper surfaces of the plurality of dams DAM1 and DAM2 included in the dam structure DAM. That is, the upper surface of the blocking member BLM may be formed in a higher position than the upper surfaces of the plurality of dams DAM1 and DAM2 included in the dam structure DAM. Meanwhile, when the difference in height between the upper surface of the blocking member BLM and the upper surface of the inorganic encapsulation layers TFE1 and TFE3 disposed on the plurality of dams DAM1 and DAM2 is defined as a protruding height d2 of the blocking member BLM, the protruding height d2 may be about 2 micrometers or less.

In an embodiment and referring to FIG. 8C, the blocking member BLM-2 may have a multi-layer structure. The blocking member BLM-2 may have a structure in which a first blocking layer BLM-L1 and a second blocking layer BLM-L2 are stacked. In an embodiment, the first blocking layer BLM-L1 may be disposed in the separation space GP defined between the first dam DAM1 and the second dam DAM2, and the second blocking layer BLM-L2 may be disposed on the first blocking layer BLM-L1 such that the upper surface of the second blocking layer BLM-L2 is located in a higher position than the upper surfaces of the plurality of dams DAM1 and DAM2.

In an embodiment, the first blocking layer BLM-L1 and the second blocking layer BLM-L2 may include different materials. In an embodiment, the first blocking layer BLM-L1 and the black matrix 310 may include a same material. The second blocking layer BLM-L2 and the plurality of color filters 320 may include a same material. The second blocking layer BLM-L2 and one of the plurality of color filters 320 may include a same material. For example, the plurality of color filters 320 may include a red filter, a green filter, and a blue filter, and the second blocking layer BLM-L2 and at least one of the red filter, the green filter, and the blue filter may include the same material.

In an embodiment and referring to FIG. 8D, a portion of the blocking member BLM-3 may be disposed in the separation space GP defined between the first dam DAM1 and the second dam DAM2, and the remaining portion of the blocking member BLM-3 may be disposed on at least one of the plurality of dams DAM1 and DAM2. For example, as illustrated in FIG. 8D, the remaining portion of the blocking member BLM-3 may be disposed on the second dam DAM2. However, without being limited thereto, the blocking member BLM-3 may be disposed on the first dam DAM1 or may be disposed on the first dam DAM1 and the second dam DAM2 by patterning. Although not illustrated, a plurality of blocking members BML-3 may be provided by patterning.

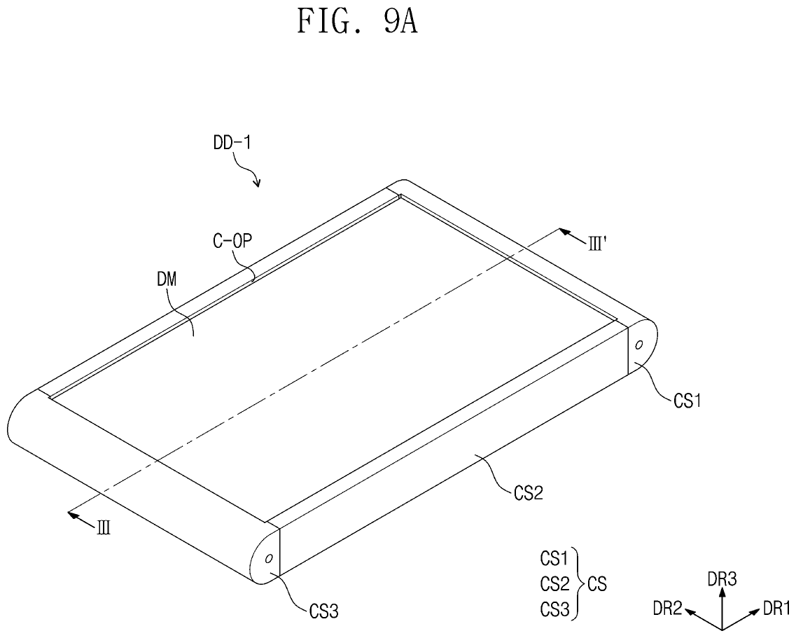

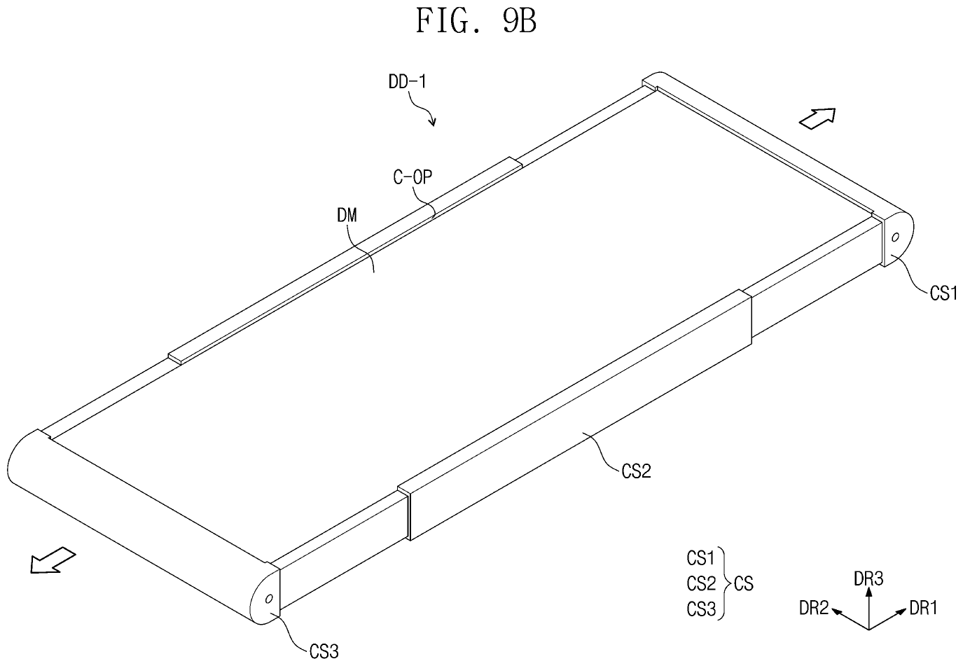

FIGS. 9A and 9B are perspective views of a display device according to an embodiment. FIG. 9A is a perspective view of the display device DD-1 operating in a first mode, and FIG. 9B is a perspective view of the display device DD-1 operating in a second mode. An embodiment of the display device DD-1 different from the display device DD illustrated in FIGS. 1A to 8D is illustrated in FIGS. 9A and 9B.

In an embodiment and referring to FIGS. 9A and 9B, a case CS in which a display module DM is accommodated may include a first case CS1, a second case CS2, and a third case CS3. The first case CS1, second case CS2 and third case CS3 may be coupled together and may accommodate the display module DM. The first case CS1 may be coupled to the second case CS2 to move in a direction that is parallel to a first direction DR1, and the third case CS3 may be coupled to the second case CS2 to move in a direction that is opposite to the first direction DR1. The first case CS1 and the third case CS3 may be coupled to the second case CS2 and may move toward or away from the second case CS2. At least a portion of the display module DM may be exposed to the outside through a display opening C-OP defined in an upper portion of the case CS, and a display surface of the display module DM exposed by the display opening C-OP, wherein the display surface may be directed parallel to the first direction DR1 and a second direction DR2 crossing the first direction DR1. The display module DM may display an image in a third direction DR3 on the display surface, wherein the display device surface is directed parallel to the first direction DR1 and the second direction DR2.

In an embodiment and referring to FIGS. 9A and 9B, the area of the display surface of the display module DM exposed by the display opening C-OP of the case CS may be adjusted depending on movement of the first case CS1 and the third case CS3. As the first case CS1 and the third case CS3 move, the opening area of the display opening C-OP may increase in the first direction DR1.

In an embodiment, when the first case CS1 moves in the first direction DR1, a support layer connected to the first case CS1 may also move together in the first direction DR1, and when the third case CS3 moves in the direction opposite to the first direction DR1, a support layer connected to the third case CS3 may also move together in the direction opposite to the first direction DR1. Due to this, the display module DM disposed on a support layer may also move in the first direction DR1 or the direction opposite to the first direction DR1 depending on the movement of the first case CS1 and the third case CS3. As ends of the display module DM move together with the first case CS1 and the third case CS3, portions of the display module DM received in the second case CS2 in the first mode may be exposed to the outside, and the display surface of the display module DM exposed through the display opening C-OP may be extended.

In an embodiment, FIG. 9A illustrates the display device DD-1 in the first mode in which the first case CS1 and the third case CS3 are disposed closest to the second case CS2 in the first direction DR1, among operating states of the display device DD-1. In the first mode, one portion extending from one region of the display module DM exposed by the display opening C-OP may be folded with a certain curvature and may be received in the second case CS2. The first mode in which the display surface of the display module DM is set to a default size may be defined as a default mode.

In an embodiment, FIG. 9B illustrates the display device DD-1 in the second mode in which the first case CS1 and the third case CS3 are disposed furthest from the second case CS2 in directions parallel to the first direction DR1, among the operating states of the display device DD-1. When the display device DD-1 is in the second mode, the area of the display surface of the display module DM exposed by the display opening C-OP may be increased, as compared with when the display device DD-1 is in the first mode. That is, the second mode in which the display surface is extended in the default mode may be defined as an extended mode.

In an embodiment, the first mode and the second mode of the display device DD-1 may be determined depending on a sliding operation of the case CS and the display module DM. By switching the operating mode of the display device DD-1 from the first mode to the second mode, a user may extend the display surface of the display device DD-1 and may visually recognize an image through the extended display surface. In addition, by switching the operating mode of the display device DD-1 from the second mode to the first mode, the user may reduce the display surface of the display device DD-1 and may visually recognize an image through the reduced display surface. That is, by selecting one of the first mode and the second mode, the user may diversely adjust the area of the display surface of the display device DD-1 exposed from the case CS.

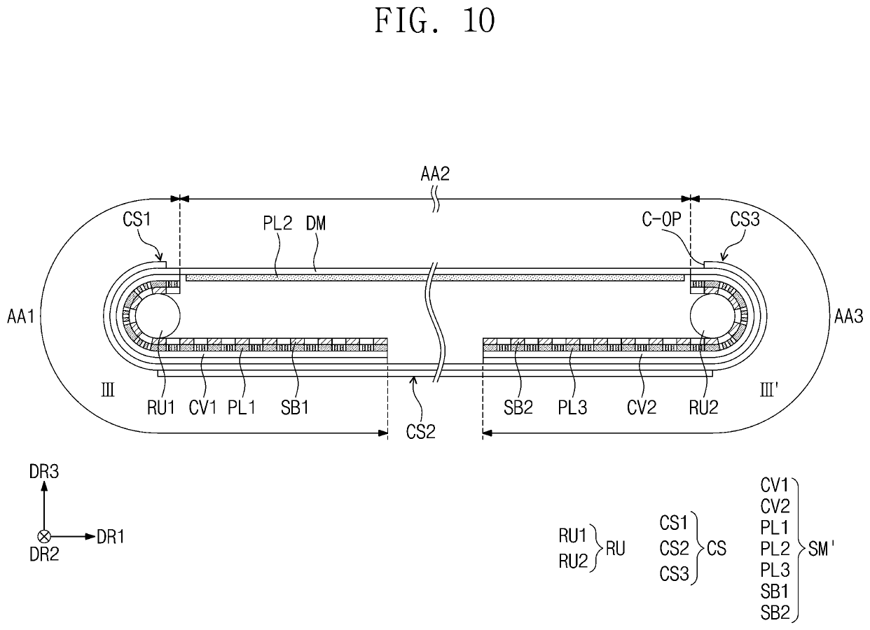

FIG. 10 is a sectional view of the display device according to an embodiment. FIG. 10 is a sectional view of the display device corresponding to line III-III′ of FIG. 9A.

In an embodiment and referring to FIG. 10, the display device DD-1 may include the case CS and the display module DM, a rotation unit RU, and a support module SM′ that are accommodated in the case CS, where the rotation unit RU may include a first rotation unit RU1 and a second rotation unit RU2. The support module SM′ may include a first cover member CV1, a second cover member CV2, a first support layer PL1, a second support layer PL2, a third support layer PL3, first support bars SB1, and second support bars SB2.

In an embodiment, the display module DM may include a first region AA1, a second region AA2 extending from the first region AA1 in the first direction DR1, and a third region AA3 spaced apart from the first region AA1 with the second region AA2 disposed therebetween. The first region AA1 may be a region supported by the first cover member CV1 and the first support layer PL1, the second region AA2 may be a region supported by the second support layer PL2, and a third region AA3 may be a region supported by the second cover member CV2 and the third support layer PL3.

In an embodiment and referring to FIG. 10, in the first mode, the display surface of the display module DM that corresponds to the second region AA2 may be exposed to the outside. In the first mode, the second region AA2 may be directed parallel to the first direction DR1 and the second direction DR2. The second region AA2 may be defined as a planar region. A portion of the first region AA1 may be folded such that an end spaced apart from the second region AA2 overlaps the second region AA2 in the third direction DR3. A portion of the third region AA3 may be folded such that an end spaced apart from the second region AA2 overlaps the second region AA2 in the third direction DR3. The first region AA1 and the third region AA3 may be defined as folding regions. In the first mode, at least a portion of the first region AA1 and at least a portion of the third region AA3 may not be exposed to the outside. As illustrated in FIG. 10, in the first mode, only portions of the first region AA1 and the third region AA3 that are disposed adjacent to the second region AA2 may be exposed to the outside.

In an embodiment, the first rotation unit RU1 and the second rotation unit RU2 may be received in the second case CS2. The first rotation unit RU1 and the second rotation unit RU2 may be rotated about rotational axes directed parallel to one direction, respectively. In FIG. 10, the first rotation unit RU1 and the second rotation unit RU2 rotatable about rotational axes parallel to the second direction DR2 are illustrated. The first rotation unit RU1 and the second rotation unit RU2 may be coupled to the second case CS2 and may rotate about the rotational axes depending on a sliding operation in which the first case CS1 and the third case CS3 move away from or toward the second case CS2. Meanwhile, the first rotation unit RU1 and the second rotation unit RU2 may rotate in opposite directions.

In an embodiment, as the first case CS1 and the third case CS3 of FIG. move away from the second case CS2 in the first direction DR1, the operating mode of the display device DD-1 may be switched from the first mode to the second mode described above with reference to FIG. 9B. When the operating mode of the display device DD-1 is switched from the first mode to the second mode, an end of the second region AA2 of the display module DM spaced apart from the first region AA1 and fixedly coupled to the first case CS1 may move together depending on the movement of the first case CS1. When the operating mode of the display device DD-1 is switched from the first mode to the second mode, an end of the second region AA2 of the display module DM spaced apart from the third region AA3 and fixedly coupled to the third case CS3 may move together depending on the movement of the third case CS3.

In an embodiment, a portion of the first region AA1 of the display module DM, and portions of the first cover member CV1, the first support layer PL1, and the first support bars SB1 that support the first region AA1 of the display module DM may be disposed on a curved surface of the first rotation unit RU1 and may be folded with a certain curvature. A portion of the third region AA3 of the display module DM, and portions of the second cover member CV2, the third support layer PL3, and the second support bars SB2 that support the third region AA3 of the display module DM may be disposed on a curved surface of the second rotation unit RU2 and may be folded with a certain curvature. In some embodiments, when the operating mode of the display device DD-1 is switched from the first mode to the second mode, the areas by which the first region AA1 and the third region AA3 are exposed to the outside by the display opening C-OP may be increased.

In an embodiment, the support module SM′ supporting the first region AA1 folded along the curved surface of the first rotation unit RU1 in the first mode and the second mode, the support module SM′ supporting the third region AA3 folded along the curved surface of the second rotation unit RU2 in the first mode and the second mode, and the support module SM′ supporting the second region AA2 remaining flat in the first mode and the second mode may include different components because required mechanical characteristics are different from one another. For example, a part of the support module SM′ supporting the first region AA1 of the display module DM may include the first cover member CV1, the first support layer PL1, and the first support bars SB1, a part of the support module SM′ supporting the second region AA2 may include the second support layer PL2, and a part of the support module SM′ supporting the third region AA3 may include the second cover member CV2, the third support layer PL3, and the second support bars SB2.

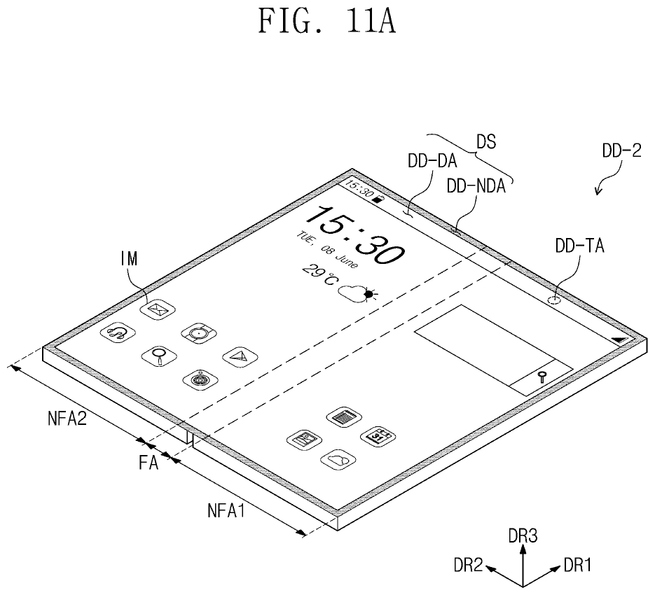

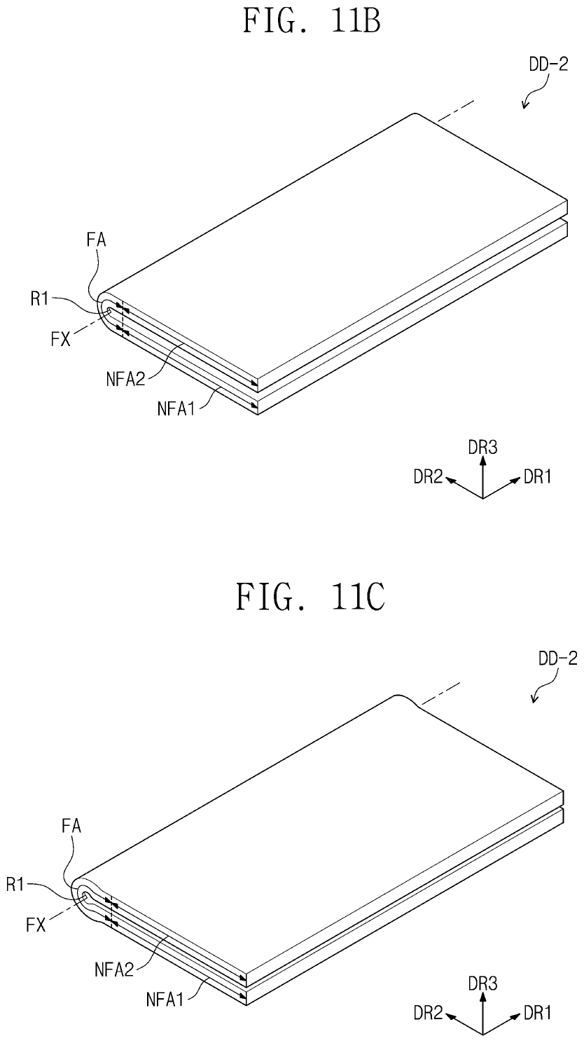

FIGS. 11A to 11C are perspective views of a display device according to an embodiment. FIG. 11A illustrates an unfolded state, and FIGS. 11B and 11C illustrate a folded state. FIGS. 11A to 11C illustrate the display device DD-2 different from the display device DD illustrated in FIGS. 1A to 8D and the display device DD-1 illustrated in FIGS. 9A to 10.

Referring to FIGS. 11A to 11C, the display device DD-2 according to an embodiment may include a display surface DS defined by a first direction DR1 and a second direction DR2 crossing the first direction DR1. The display device DD-2 may provide an image IM to a user through the display surface DS.

In an embodiment, the display surface DS may include a display region DD-DA and a non-display region DD-NDA around the display region DD-DA. The display region DD-DA may display the image IM, and the non-display region DD-NDA may not display the image IM. The non-display region DD-NDA may surround the display region DD-DA. However, without being limited thereto, the shape of the display region DD-DA and the shape of the non-display region DD-NDA may be modified.

In an embodiment, the display surface DS may include a sensing region DD-TA. The sensing region DD-TA may be a partial region of the display region DD-DA. The sensing region DD-TA has a higher transmittance than the other region of the display region DD-DA. Hereinafter, the other region of the display region DD-DA other than the sensing region DD-TA may be defined as a general display region.

In an embodiment, an optical signal, for example, visible light or infrared light may travel through the sensing region DD-TA. The display device DD-2 may take an image of an external object through visible light passing through the sensing region DD-TA or may determine accessibility of the external object through infrared light passing through the sensing region DD-TA. In FIG. 11A, one sensing region DD-TA is illustrated as an example. However, without being limited thereto, a plurality of sensing regions DD-TA may be provided.

In an embodiment, the display device DD-2 may include a folding region FA and a plurality of non-folding regions NFA1 and NFA2. The non-folding regions NFA1 and NFA2 may include the first non-folding region NFA1 and the second non-folding region NFA2. The folding region FA may be disposed between the first non-folding region NFA1 and the second non-folding region NFA2 in the second direction DR2.

In an embodiment and as illustrated in FIG. 11B, the folding region FA may be folded about a folding axis FX which is directed parallel to the first direction DR1. The folding region FA has a certain curvature and a radius of curvature R1. The display device DD-2 may be folded in an in-folding manner such that the first non-folding region NFA1 and the second non-folding region NFA 2 face each other and the display surface DS is not exposed to the outside.

Although not illustrated, in an embodiment, the display device DD-2 may be folded in an out-folding manner such that the display surface DS is exposed to the outside. In an embodiment, the display device DD-2 may be configured such that an in-folding operation and an out-folding operation are mutually repeated from an unfolding operation. However, the invention is not limited thereto. In an embodiment, the display device DD-2 may be configured to select one of an unfolding operation, an in-folding operation, and an out-folding operation.

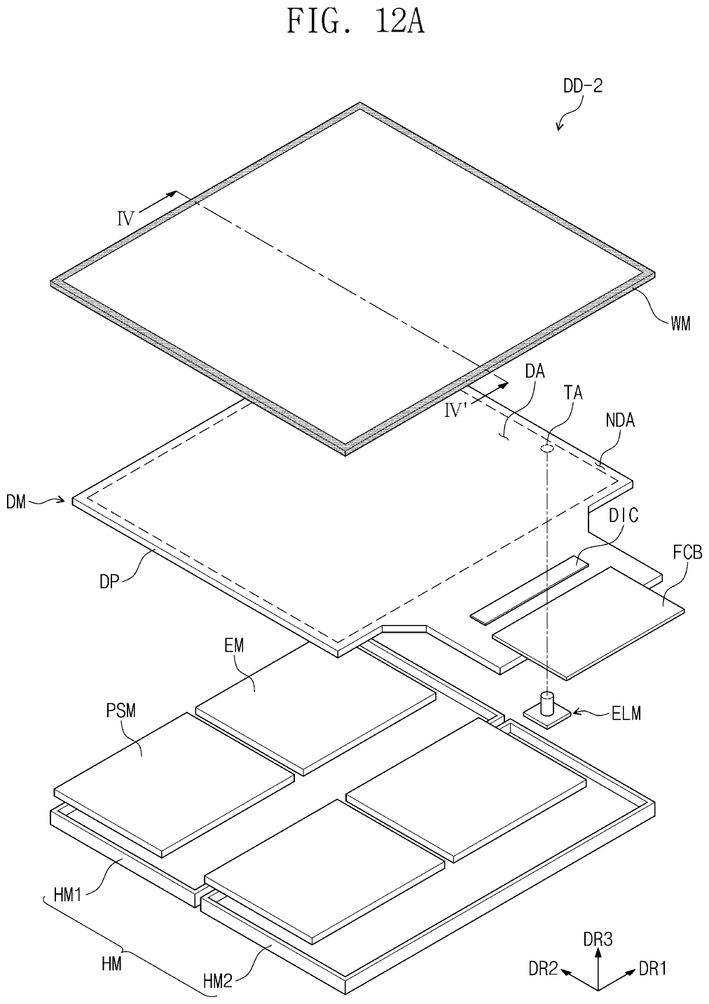

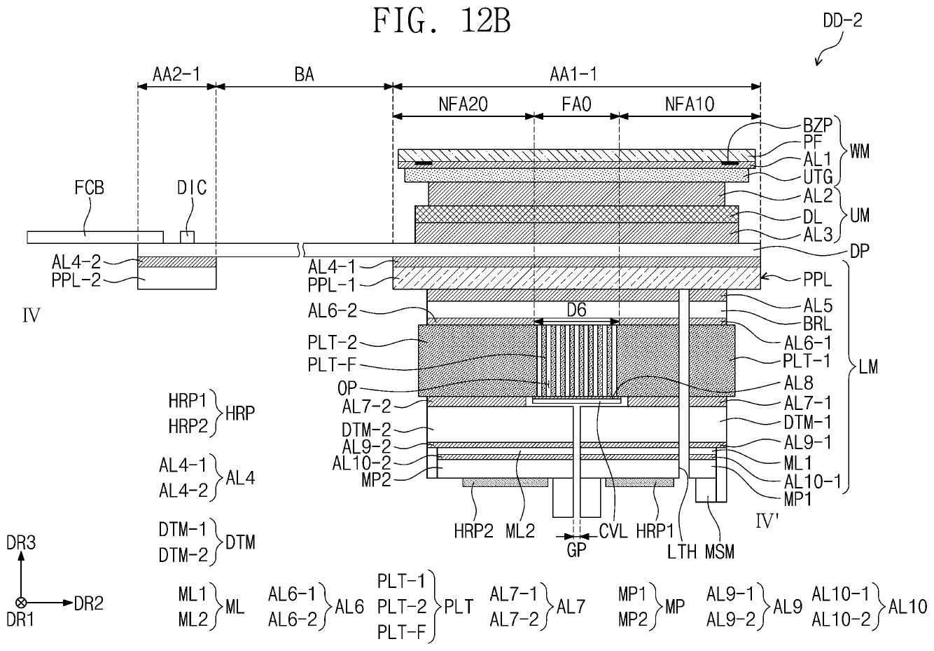

In an embodiment and as illustrated in FIG. 11B, the distance between the first non-folding region NFA1 and the second non-folding region NFA2 may be substantially the same as the radius of curvature R1. However, as illustrated in FIG. 11C, the distance between the first non-folding region NFA1 and the second non-folding region NFA2 may be smaller than the radius of curvature R1. FIGS. 11B and 11C are illustrated based on the display surface DS, and a housing HM (refer to FIG. 12A) that forms the exterior of the display device DD-2 may make contact with distal end regions of the first non-folding region NFA1 and the second non-folding region NFA2.

FIG. 12A is an exploded perspective view of the display device according to an embodiment. FIG. 12B is a sectional view of the display device according to an embodiment. In FIG. 12B, a section taken along line IV-IV′ illustrated in FIG. 12A is illustrated.

In an embodiment and as illustrated in FIGS. 12A and 12B, the display device DD-2 may include a window WM, a display module DM, electronic modules EM, an electro-optical module ELM, power supply modules PSM, and the housing HM. Although not separately illustrated, the display device DD-2 may further include a mechanical structure for controlling a folding operation of the display device DD-2.

In an embodiment, the window WM provides a front surface of the display device DD-2. The display module DM generates an image and detects an external input. The display module DM may include at least a display panel DP. The contents described with reference to FIGS. 4 to 8D may be identically applied to the display module DM and the display panel DP.

In an embodiment, the display panel DP includes a display region DA and a non-display region NDA that correspond to the display region DD-DA (refer to FIG. 11A) and the non-display region DD-NDA (refer to FIG. 11A) of the display device DD-2, respectively.

In an embodiment, the display panel DP may include a sensing region TA corresponding to the sensing region DD-TA of FIG. 11A. The sensing region TA may have a lower resolution than the display region DA.

In an embodiment and as illustrated in FIG. 12A, a driver ICDIC may be disposed on the non-display region NDA of the display panel DP. A flexible circuit board FCB may be coupled to the non-display region NDA of the display panel DP. The flexible circuit board FCB may be connected to a main circuit board. The main circuit board may be one electronic part constituting the electronic modules EM. In an embodiment, the driver IC DIC may include drive elements (e.g., a data drive circuit) for driving pixels of the display panel DP. Although FIG. 12A illustrates a structure in which the driver IC DIC is mounted on the display panel DP, the invention is not limited thereto. For example, the driver IC DIC may be mounted on the flexible circuit board FCB.

In an embodiment and referring to FIG. 12A, the electronic modules EM may be disposed in a first housing HM1 and a second housing HM2, and the power supply modules PSM may be disposed in the first housing HM1 and the second housing HM2. Although not illustrated, the electronic module EM disposed in the first housing HM1 and the electronic module EM disposed in the second housing HM2 may be electrically connected with each other through a flexible circuit board. The electronic modules EM may include a control module for controlling operation of the display device DD-2. The electronic modules EM may include a wireless communication module, an image input module, sound input/output modules, a memory, an external interface module, and the like, in addition to the control module.

In an embodiment, the power supply modules PSM supply power required for overall operation of the display device DD-2. The power supply modules PSM may include a conventional battery device.

In an embodiment, the electro-optical module ELM may be an electronic part that outputs or receives an optical signal. The electro-optical module ELM may include a camera module and/or a proximity sensor. The camera module may take an image of an external object through the sensing region TA. The proximity sensor may receive an external signal recognized through the sensing region TA.

In an embodiment, the housing HM illustrated in FIG. 12A is coupled with the display device DD-2, particularly, the window WM and accommodates the other modules. Although the housing HM is illustrated as including the first and second housings HM1 and HM2 separated from each other, the invention is not limited thereto. Although not illustrated, the display device DD-2 may further include a hinge structure for connecting the first and second housings HM1 and HM2.

In an embodiment, FIGS. 12A and 12B illustrate an unfolded state in which the display panel DP is not bent. In another embodiment, in a state in which the display panel DP is applied and coupled to the display device DD-2 illustrated in FIGS. 11A to 11C, a bending region BA may be bent, and a second region AA2-1 may be disposed under a first region AA1-1. In the bent state, the bending region BA has a certain curvature and a certain radius of curvature. The radius of curvature may range from about 0.1 mm to about 0.5 mm.

In an embodiment and referring to FIG. 12B, the display device DD-2 includes the window WM, an upper member UM, the display panel DP, and a lower member LM. Components disposed between the window WM and the display panel DP are collectively referred to as the upper member UM, and components disposed under the display panel DP are collectively referred to as the lower member LM.

In an embodiment, the window WM may include a thin glass substrate UTG, a window protection layer PF disposed on the thin glass substrate UTG, and a bezel pattern BZP disposed on a lower surface of the window protection layer PF. In an embodiment, the window protection layer PF may include a synthetic resin film. The window WM may include an adhesive layer AL1 (hereinafter, referred to as the first adhesive layer) that couples the window protection layer PF and the thin glass substrate UTG.

In an embodiment, the bezel pattern BZP overlaps the non-display region DD-NDA illustrated in FIG. 11A. The bezel pattern BZP may be disposed on one surface of the thin glass substrate UTG or one surface of the window protection layer PF. FIG. 12B exemplarily illustrates the bezel pattern BZP disposed on the lower surface of the window protection layer PF. However, without being limited thereto, the bezel pattern BZP may be disposed on an upper surface of the window protection layer PF. The bezel pattern BZP may be a colored light-blocking film and may be formed by, for example, a coating method. The bezel pattern BZP may include a base material and a dye or a pigment mixed with the base material.

In an embodiment, the thin glass substrate UTG may have a thickness of about 15 micrometers to about 45 micrometers. For example, the thin glass substrate UTG may have a thickness of about 30 micrometers. The thin glass substrate UTG may be a chemically strengthened glass substrate. The occurrence of a fold in the thin glass substrate UTG may be minimized even though the thin glass substrate UTG is repeatedly folded and unfolded.

In an embodiment, the window protection layer PF may have a thickness of about 50 micrometers to about 80 micrometers. For example, the window protection layer PF may have a thickness of about 70 micrometers. The synthetic resin film of the window protection layer PF may include polyimide, polycarbonate, polyamide, triacetylcellulose, polymethylmethacrylate, or polyethylene terephthalate. Although not separately illustrated, at least one of a hard coating layer, an anti-fingerprint layer, and an anti-reflective layer may be disposed on the upper surface of the window protection layer PF.

In an embodiment, the first adhesive layer AL1 may be a pressure sensitive adhesive (PSA) film or an optically clear adhesive (OCA) member. Adhesive layers to be described below may also include the same adhesive as the first adhesive layer AL1.

In an embodiment, the first adhesive layer AL1 may be separated from the thin glass substrate UTG. The window protection layer PF may be relatively easily scratched because the window protection layer PF has a lower strength than the thin glass substrate UTG. A new window protection layer PF may be attached to the thin glass substrate UTG after the first adhesive layer AL1 and the window protection layer PF are separated. For example, the first adhesive layer AL1 may have a thickness of about 20 micrometers to about 50 micrometers.

In an embodiment, on the plane, the edge of the thin glass substrate UTG may not overlap the bezel pattern BZP. As the aforementioned condition is satisfied, the edge of the thin glass substrate UTG may be exposed from the bezel pattern BZP, and micro cracks generated at the edge of the thin glass substrate UTG may be examined through an inspection device.

In an embodiment, the upper member UM includes an upper film DL. The upper film DL may include a synthetic resin film. The synthetic resin film may include polyimide, polycarbonate, polyamide, triacetylcellulose, polymethylmethacrylate, or polyethylene terephthalate.

In an embodiment, the upper film DL may absorb an external impact applied to the front surface of the display device DD-2. In an embodiment, the upper film DL may be omitted. The upper film DL may have a thickness of about 10 micrometers to about 40 micrometers. For example, the upper film DL may have a thickness of about 23 micrometers.

In an embodiment, the upper member UM may include a second adhesive layer AL2 that couples the upper film DL and the window WM and a third adhesive layer AL3 that couples the upper film DL and the display panel DP. The second adhesive layer AL2 may have a thickness of about 50 micrometers to about 100 micrometers. For example, the second adhesive layer AL2 may have a thickness of about 75 micrometers. The third adhesive layer AL3 may have a thickness of about micrometers to about 70 micrometers.

In an embodiment, the lower member LM may include a protective film PPL, a barrier layer BRL, a support member PLT, a cover layer CVL, a digitizer DTM, a metal layer ML, a metal plate MP, a heat radiating layer HRP, and fourth to tenth adhesive layers AL4 to AL10, respectively. The fourth to tenth adhesive layers ALA to AL10, respectively, may include an adhesive such as a pressure sensitive adhesive or an optically clear adhesive. In an embodiment, some of the aforementioned components may be omitted. For example, the metal plate MP or the heat radiating layer HRP and an adhesive layer related thereto may be omitted.

In an embodiment, the protective film PPL is disposed under the display panel DP. The protective film PPL may protect a lower portion of the display panel DP. The protective film PPL may include a flexible synthetic resin film. The flexible synthetic resin film included in the protective film PPL may be a heat-resistant synthetic resin film. For example, the protective film PPL may include heat-resistant polyethylene terephthalate. However, without being limited thereto, the protective film PPL may include a heat-resistant synthetic resin material such as polyamide-imide, polyether ether ketone, polyphenylene sulfide, or the like.

In an embodiment, the protective film PPL may not be disposed in the bending region BA. The protective film PPL may include a first protective film PPL-1 that protects the first region AA1-1 of the display panel DP and a second protective film PPL-2 that protects the second region AA2-1 of the display panel DP.

In an embodiment, the fourth adhesive layer AL4 couples the protective film PPL and the display panel DP. The fourth adhesive layer AL4 may include a first portion ALA-1 corresponding to the first protective film PPL-1 and a second portion AL4-2 corresponding to the second protective film PPL-2. The fourth adhesive layer AL4 may have a thickness of about 15 micrometers to about 35 micrometers. For example, the fourth adhesive layer ALA may have a thickness of about 25 micrometers.

In an embodiment, when the bending region BA is bent, the second protective film PPL-2, together with the second region AA2-1, may be disposed under the first region AA1-1 and the first protective film PPL-1. The bending region BA may be more easily bent because the protective film PPL is not disposed in the bending region BA. The second protective film PPL-2 may be attached to the bottom of the metal plate MP through an additional adhesive layer AL11. In an embodiment, the additional adhesive layer AL11 may be omitted.

In an embodiment, a bending protection layer BPL is disposed at least in the bending region BA. The bending protection layer BPL may overlap the bending region BA, the first region AA1-1, and the second region AA2-1. The bending protection layer BPL may be disposed on a portion of the first region AA1-1 and a portion of the second region AA2-1.

In an embodiment, the bending protection layer BPL may be bent together with the bending region BA. The bending protection layer BPL protects the bending region BA from an external impact and controls the neutral plane of the bending region BA. The bending protection layer BPL controls stress of the bending region BA such that the neutral plane approaches signal lines disposed in the bending region BA.

In an embodiment and as illustrated in FIG. 12B, the fifth adhesive layer AL5 couples the protective film PPL and the barrier layer BRL. The barrier layer BRL may be disposed under the protective film PPL. The barrier layer BRL may increase resistance to a compressive force caused by external pressing. Accordingly, the barrier layer BRL may serve to prevent deformation of the display panel DP. The barrier layer BRL may include a flexible plastic material such as polyimide or polyethylene terephthalate. Furthermore, the barrier layer BRL may be a colored film having a low light transmittance. The barrier layer BRL may absorb light incident from the outside. For example, the barrier layer BRL may be a black synthetic resin film. Components disposed under the barrier layer BRL may not be visible to a user when the display device DD-2 is viewed from above the window protection layer PF. The barrier layer BRL may have a thickness of about 30 micrometers to about 80 micrometers.

In an embodiment, the sixth adhesive layer AL6 couples the barrier layer BRL and the support member PLT. The sixth adhesive layer AL6 may include a first portion AL6-1 and a second portion AL6-2 spaced apart from each other. The separation distance D6 (or, the gap) between the first portion AL6-1 and the second portion AL6-2 corresponds to the width of a folding region FAO and is greater than a gap GP to be described below. The separation distance D6 between the first portion AL6-1 and the second portion AL6-2 may range from about 7 mm to about 15 mm, preferably, from about 9 mm to about 13 mm.

In an embodiment, the first portion AL6-1 and the second portion AL6-2 are defined as different portions of one adhesive layer. However, the invention is not limited thereto. When the first portion AL6-1 is defined as one adhesive layer (e.g., a first adhesive layer or a second adhesive layer), the second portion AL6-2 may be defined as another adhesive layer (e.g., the second adhesive layer or a third adhesive layer). The above-described definition may be applied not only to the sixth adhesive layer AL6 but also to adhesive layers including two portions among adhesive layers to be described below.

In this specification, the fifth adhesive layer AL5 and the sixth adhesive layer AL6 may be referred to as lower adhesive layers. In an embodiment, the fifth adhesive layer AL5 and the sixth adhesive layer AL6 may have a thickness of about micrometers to about 35 micrometers.

In an embodiment, the support member PLT is disposed under the barrier layer BRL. The support member PLT supports components disposed on the support member PLT and maintains an unfolded state and a folded state of the display device DD-2. The support member PLT has a greater strength than the barrier layer BRL. The support member PLT includes at least a first support portion PLT-1 corresponding to a first non-folding region NFA10 and a second support portion PLT-2 corresponding to a second non-folding region NFA20. The first support portion PLT-1 and the second support portion PLT-2 are spaced apart from each other in the second direction DR2. The support member PLT may have a thickness of about 150 micrometers to about 200 micrometers.

In an embodiment, the support member PLT may include a folding portion PLT-F that corresponds to the folding region FAO and has a plurality of openings OP defined therein and that is disposed between the first support portion PLT-1 and the second support portion PLT-2. The plurality of openings OP may be arranged such that the folding region FAO has a lattice shape on the plane. The first support portion PLT-1, the second support portion PLT-2, and the folding portion PLT-F may have an integral shape.

In an embodiment, the folding portion PLT_F may prevent infiltration of foreign matter into an open central region of the barrier layer BRL from the first support portion PLT_1 and the second support portion PLT_2 during the folding operation illustrated in FIGS. 11B and 11C. The flexibility of the folding portion PLT-F is improved by the plurality of openings OP. Furthermore, the flexibility of the support member PLT may be improved because the sixth adhesive layer AL6 is not disposed on the folding portion PLT-F. In an embodiment, the folding portion PLT-F may be omitted. In this case, the support member PLT includes the first support portion PLT-1 and the second support portion PLT-2 spaced apart from each other.

In an embodiment, the support member PLT may be selected from materials capable of transmitting an electro-magnetic field generated from the digitizer DTM, which will be described below, without loss or with minimal loss. The support member PLT may include a non-metallic material. The support member PLT may include a fiber reinforced composite. The support member PLT may include reinforced fibers disposed inside a matrix part. The reinforced fibers may be carbon fibers or glass fibers. The matrix part may include a polymer resin. The matrix part may include a thermoplastic resin. For example, the matrix part may include a polyamide-based resin or a polypropylene-based resin. For example, the fiber reinforced composite may be carbon fiber reinforced plastic (CFRP) or glass fiber reinforced plastic (GFRP).

In an embodiment, the cover layer CVL and the digitizer DTM are disposed under the support member PLT. The cover layer CVL is disposed to overlap the folding region FAO. The digitizer DTM may include a first digitizer DTM-1 and a second digitizer DTM-2 that overlap the first support portion PLT-1 and the second support portion PLT-2, respectively. A portion of the first digitizer DTM-1 and a portion of the second digitizer DTM-2 may be disposed under the cover layer CVL.

In an embodiment, the seventh adhesive layer AL7 couples the support member PLT and the digitizer DTM, and the eighth adhesive layer AL8 couples the cover layer CVL and the support member PLT. The seventh adhesive layer AL7 may include a first portion AL7-1 that couples the first support portion PLT-1 and the first digitizer DTM-1 and a second portion AL7-2 that couples the second support portion PLT-2 and the second digitizer DTM-2.

In an embodiment, the cover layer CVL may be disposed between the first portion AL7-1 and the second portion AL7-2 in the second direction DR2. The contents described with reference to FIGS. 6, 7A, and 7B may be identically applied to the cover layer CVL.

In an embodiment, the digitizer DTM, also called the EMR sensing panel, includes a plurality of loop coils that generate a magnetic field of a preset resonant frequency with an electronic pen. The magnetic field formed by the loop coils is applied to an LC resonance circuit of the electronic pen that is constituted by an inductor (coil) and a capacitor. The coil generates electric current by the received magnetic field and transfers the generated electric current to the capacitor. The capacitor charges the electric current input from the coil and discharges the charged electric current to the coil. Accordingly, a magnetic field of a resonant frequency is emitted to the coil. The magnetic field emitted by the electronic pen may be absorbed by the loop coils of the digitizer DTM again, and thus a position in which the electronic pen approaches a touch screen may be determined.

In an embodiment, the first digitizer DTM-1 and the second digitizer DTM-2 are spaced apart from each other by the predetermined gap GP. The gap GP may range from about 0.3 mm to about 3 mm and may be located to correspond to the folding region FAO.

In an embodiment, the metal layer ML is disposed under the digitizer DTM. The metal layer ML may include a first metal layer ML1 and a second metal layer ML2 that overlap the first support portion PLT-1 and the second support portion PLT-2, respectively. The metal layer ML may release heat generated during operation of the digitizer DTM to the outside. The metal layer ML transfers the heat generated from the digitizer DTM to the lower side. The metal layer ML may have a higher electrical conductivity and a higher thermal conductivity than the metal plate MP to be described below. The metal layer ML may include copper or aluminum.

In an embodiment, the ninth adhesive layer AL9 couples the digitizer DTM and the metal layer ML. The ninth adhesive layer AL9 may include a first portion AL9-1 and a second portion AL9-2 that correspond to the first metal layer ML1 and the second metal layer ML2, respectively.

In an embodiment, the metal plate MP is disposed under the metal layer ML. The metal plate MP may include a first metal plate MP1 and a second metal plate MP2 that overlap the first metal layer ML1 and the second metal layer ML2, respectively. The metal plate MP may absorb an external impact applied from below.

In an embodiment, the metal plate MP may have a higher strength and a greater thickness than the metal layer ML. The metal plate MP may include a metallic material such as stainless steel.

In an embodiment, the tenth adhesive layer AL10 couples the metal layer ML and the metal plate MP. The tenth adhesive layer AL10 may include a first portion AL10-1 and a second portion AL10-2 that correspond to the first metal plate MP1 and the second metal plate MP2, respectively.

In an embodiment, the heat radiating layer HRP may be disposed under the metal plate MP. The heat radiating layer HRP may include a first heat radiating layer HRP1 and a second heat radiating layer HRP2 that overlap the first metal plate MP1 and the second metal plate MP2, respectively. The heat radiating layer HRP releases heat generated from electronic parts disposed under the heat radiating layer HRP. The electronic parts may be the electronic modules EM illustrated in FIGS. 2A and 2B. The heat radiating layer HRP may have a structure in which adhesive layers and graphite layers are alternately stacked one above another. The outermost adhesive layer may be attached to the metal plate MP.

In an embodiment, a magnetic-field shielding sheet MSM is disposed under the metal plate MP. The magnetic-field shielding sheet MSM shields a magnetic field generated from a magnetic material (not illustrated) that is disposed under the magnetic-field shielding sheet MSM. The magnetic-field shielding sheet MSM may prevent the magnetic field generated from the magnetic material from interfering with the digitizer DTM.

In an embodiment, the magnetic-field shielding sheet MSM includes a plurality of portions. At least some of the plurality of portions may have different thicknesses. The plurality of portions may be disposed to correspond to steps of a bracket (not illustrated) that is disposed on a lower side of the display device DD-2. The magnetic-field shielding sheet MSM may have a structure in which magnetic-field shielding layers and adhesive layers are alternately stacked one above another. A portion of the magnetic-field shielding sheet MSM may be directly attached to the metal plate MP.

In an embodiment, a through-hole LTH may be formed through some members of the lower member LM. The through-hole LTH is disposed to overlap the sensing region TA of FIG. 12A. As illustrated in FIG. 12B, the through-hole LTH may penetrate from the fifth adhesive layer AL5 to the metal plate MP. The through-hole LTH may correspond to a state in which a light blocking structure is removed on the path of an optical signal. The through-hole LTH may improve efficiency in receiving an optical signal by the electro-optical module ELM.

According to embodiments of the invention, defects such as cracks in the display panel may be prevented in the operation of extending the display surface. Accordingly, the durability of the display device including the display module may be improved.

Although the description has been made above with reference to an embodiment of the invention, it may be understood that those skilled in the art or those having ordinary knowledge in the art may variously modify and change the invention without departing from the spirit and technical scope of the invention described in the appended claims. Accordingly, the technical scope of the invention is not limited to the detailed description of the specification, but should be defined by the appended claims. Moreover, the embodiments or parts of the embodiments may be combined in whole or in part without departing from the scope of the invention.

What is claimed is:

1. A display device comprising:
a display module including a first region and a second region arranged in a first direction;
a first support layer disposed under the display module and configured to overlap the first region, the first support layer having a plurality of openings defined therein; and
a second support layer disposed under the display module and configured to overlap the second region, the second support layer being spaced apart from the first support layer in the first direction,
wherein the display module includes:
a base layer including a display region and a non-display region disposed adjacent to the display region;
a circuit layer disposed on the base layer;
a light emitting element layer disposed on the circuit layer, the light emitting element layer including at least one light emitting element; and
an anti-reflective layer disposed on the light emitting element layer, the anti-reflective layer including at least one organic pattern and an overcoat layer configured to cover the at least one organic pattern,
wherein the circuit layer includes:
a dam structure disposed on the non-display region, the dam structure including at least one dam; and
a blocking member configured to overlap at least a portion of the dam structure on a plane, the blocking member including the same material as the at least one organic pattern,
wherein the overcoat layer has a thickness in a range of about 10 micrometers to about 50 micrometers, and
wherein the overcoat layer overlaps at least a portion of the blocking member on the plane.

2. The display device of claim 1, wherein the anti-reflective layer includes:
a black matrix configured to absorb light;
at least one color filter configured to transmit light having a specific wavelength; and
the overcoat layer configured to cover the black matrix and the at least one color filter, and
wherein the blocking member includes the same material as at least one of the black matrix and the at least one color filter.

3. The display device of claim 2, wherein the blocking member includes the same material as the black matrix.

4. The display device of claim 2, wherein the blocking member includes the same material as the at least one color filter.

5. The display device of claim 2, wherein the blocking member includes:
a first blocking layer including the same material as the black matrix; and
a second blocking layer disposed on the first blocking layer, the second blocking layer including the same material as the at least one color filter.

6. The display device of claim 1, wherein the dam structure includes:
a first dam disposed adjacent to the display region; and
a second dam spaced apart from the display region with the first dam disposed therebetween, and
wherein a separation space is defined between the first dam and the second dam.

7. The display device of claim 6, wherein at least a portion of the blocking member is disposed between the first dam and the second dam.

8. The display device of claim 6, wherein the blocking member overlaps at least a part of the first dam and the second dam.

9. The display device of claim 1, wherein the circuit layer includes a plurality of insulating layers, and
wherein the at least one dam includes at least one of the plurality of insulating layers.

10. The display device of claim 1, wherein the overcoat layer is in contact with the blocking member.

11. The display device of claim 1, wherein at least a portion of the first region is folded about an axis configured to extend in a second direction crossing the first direction.

12. The display device of claim 11, wherein the display module further includes a third region spaced apart from the first region with the second region disposed therebetween, and
wherein at least a portion of the third region is folded about an axis configured to extend in the second direction.

13. The display device of claim 11, wherein the display module further includes a fourth region spaced apart from the second region with the first region disposed therebetween, and
wherein an upper surface of the second region and an upper surface of the fourth region face each other in a state in which the at least a portion of the first region is folded.

14. The display device of claim 1, further comprising:
a plurality of support bars disposed under the first support layer and spaced apart from each other in the first direction, wherein each of the plurality of support bars extends in a second direction crossing the first direction.

15. The display device of claim 14, wherein the plurality of support bars do not overlap the plurality of openings on the plane.

16. The display device of claim 1, further comprising:
a cover member disposed between the display module and the first support layer, the cover member including an elastic material.

17. A display device comprising:
a display module including a first region and a second region arranged in a first direction;
a first support layer disposed under the display module and configured to overlap the first region, the first support layer having a plurality of openings defined therein; and
a second support layer disposed under the display module and configured to overlap the second region, the second support layer being spaced apart from the first support layer in the first direction,
wherein the display module includes:
a base layer including a display region and a non-display region disposed adjacent to the display region;
a circuit layer disposed on the base layer;
a light emitting element layer disposed on the circuit layer, the light emitting element layer including at least one light emitting element; and
an anti-reflective layer disposed on the light emitting element layer,
wherein the anti-reflective layer includes a black matrix configured to absorb light, at least one color filter configured to transmit light having a specific wavelength, and an overcoat layer configured to cover the black matrix and the at least one color filter,
wherein the circuit layer includes:
a dam structure disposed on the non-display region, the dam structure including at least one dam; and
a blocking member configured to overlap the dam structure on a plane, the blocking member including the same material as the black matrix or the at least one color filter, and
wherein the overcoat layer has a thickness in a range of about 10 micrometers to about 50 micrometers.

18. The display device of claim 17, wherein the dam structure includes:
a first dam disposed adjacent to the display region; and
a second dam spaced apart from the display region with the first dam disposed therebetween, and
wherein a portion of the blocking member is disposed between the first dam and the second dam.

19. The display device of claim 17, wherein the overcoat layer is in contact with the blocking member.

20. A display device configured to operate in a first mode and a second mode, wherein in the second mode, a display surface is further extended as compared with when the display device operates in the first mode, the display device comprising:
a display module including a first region, at least a portion of which is folded in the first mode and a second region disposed adjacent to the first region,
wherein the display module includes:
a base layer including a display region and a non-display region disposed adjacent to the display region;
a circuit layer disposed on the base layer;
a light emitting element layer disposed on the circuit layer, the light emitting element layer including at least one light emitting element; and
an anti-reflective layer disposed on the light emitting element layer, the anti-reflective layer including at least one organic pattern and an overcoat layer configured to cover the at least one organic pattern,
wherein the circuit layer includes:
a dam structure disposed on the non-display region, the dam structure including at least one dam; and
a blocking member configured to overlap the dam structure on a plane, the blocking member including the same material as the at least one organic pattern,
wherein the overcoat layer has a thickness range of about 10 micrometers to about 50 micrometers, and
wherein the overcoat layer is in contact with at least a portion of the blocking member.
